(19) United States
(12) Patent Application Publication
(10) Pub. No.: US 2013/0300447 A1
(43) Pub. Date: Nov. 14, 2013

(54) MANUFACTURING METHOD FOR ELECTRONIC COMPONENT, INSPECTION METHOD FOR ELECTRONIC COMPONENT, SHEET SUBSTRATE, ELECTRONIC COMPONENT, AND ELECTRONIC APPARATUS

(71) Applicant: Seiko Epson Corporation, Tokyo (JP)

(72) Inventor: Kyo HORIE, Okaya (JP)

(73) Assignee: Seiko Epson Corporation, Tokyo (JP)

(21) Appl. No.: 13/891,416

(22) Filed: May 10, 2013

(30) Foreign Application Priority Data
May 14, 2012 (JP) 2012-110169
May 16, 2012 (JP) 2012-112202

(51) Int. Cl. G01R 1/04; G01R 3/00

(52) U.S. Cl. CPC G01R 1/0408; G01R 3/00
USPC 324/756.07; 324/537; 29/837

(57) ABSTRACT

A manufacturing method for an electronic component includes arranging, across boundaries of a first substrate region, wires for electrically connecting a piezoelectric resonator element arranged in the first substrate region and a lid arranged in a second substrate regions to a sheet substrate, performing, after arranging the piezoelectric resonator element and the lid in the substrate regions, input and output of a signal to and from the piezoelectric resonator element via the lid connected to the wires, and dividing the sheet substrate in each of the boundaries.

### BACKGROUND

1. Technical Field

The present invention relates to a manufacturing method for an electronic component, an inspection method for an electronic component, a sheet substrate, an electronic component, and an electronic apparatus and, more particularly to a technique that makes it possible to easily perform an inspection after packaging of an electronic element on which an electronic component is mounted.

2. Related Art

As an efficient manufacturing method for an electronic component, a so-called multi-cavity method has been used. Specifically, a sheet substrate including a plurality of substrate regions is prepared, electronic elements such as piezoelectric transducers and ICs are arranged in the respective substrate regions, and the sheet substrate is divided into individual pieces along boundaries among the substrate regions, whereby individual electronic components are obtained.

In the electronic component, in some case, work such as an operation check is applied to the electronic element mounted on the electronic component. For example, when the electronic element is the piezoelectric vibrator, in some cases, an inspection probe is brought into contact with a connection electrode electrically connected to the piezoelectric vibrator on the substrate and it is inspected whether the piezoelectric vibrator oscillates or whether a resonance frequency, a CI value, and the like are within proper ranges. According to this work, it is possible to advance only an electronic component accepted by an inspection to the next process.

However, as the electronic component is further reduced in size, the connection electrode is manufactured extremely small, making it difficult to bring the inspection probe into contact with the connection electrode. Therefore, there is disclosed a technique for providing anew, on the sheet substrate, an inspection electrode electrically connected to the electronic element and having an area larger than the connection electrode and bringing the inspection probe into contact with the inspection electrode.

A plan view of a sheet substrate described in JP-A-2005-109783 (Patent Literature 1) is shown in FIG. 38. Patent Literature 1 discloses a sheet substrate 100 on which scribe lines 104 are arranged lengthwise and breadthwise and substrate regions 102 and inspection regions 112 are alternately sectioned. On the sheet substrate 100, regions surrounded by the scribe lines 104 of the sheet substrate 100 are formed as the substrate regions 102 and the inspection regions 112. Inspection electrodes 106 are arranged in the inspection regions 112 of the sheet substrate 100. Connection electrodes 108 connected to electronic elements (not shown in the figure) in the substrate regions 102 are arranged. The connection electrodes 108 and the inspection electrodes 106 are electrically connected to each other by wires 110 extending across the substrate regions 102 and the inspection regions 112.

In the configuration explained above, after the electronic elements (not shown in the figure) are packaged in the substrate regions 102 to be connected to the connection electrodes 108, an input and output inspection is performed for the electronic elements (not shown in the figure) via the inspection electrodes 106. After the inspection, the substrate regions 102 are singulated from the sheet substrate 100 along the scribe lines 104 and the wires 110 are fragmented.

However, in the configuration disclosed in Patent Literature 1, the inspection regions 112 are necessary to form the inspection electrodes 106. Therefore, a portion for forming the substrate regions 102 on the sheet substrate 100 decreases.

To solve this problem, as shown in FIG. 39, JP-A-2008-35486 (Patent Literature 2) discloses an electronic component 200 manufactured using a sheet substrate 202 on which first substrate regions 204 and second substrate regions 206 adjacent to each other are alternately continuously provided and including electronic elements 208 arranged in the first substrate regions 204 and inspection electrodes 210 arranged on the lower surfaces of the second substrate regions 206. The electronic elements 208 and the inspection electrodes 210 are electrically connected by wires 212 that pass the insides of the first substrate regions 204 and the second substrate regions 206.

In the configuration explained above, after inspection probes are brought into contact with the inspection electrodes 210 and an input and output inspection for the electronic elements 208 is performed via the inspection electrodes 210 and the wires 212, the sheet substrate 202 is divided along boundaries between the first substrate regions 204 and the second substrate regions 206 to singulate the electronic component 200 and fragment the wires 212.

With the configuration disclosed in Patent Literature 2, unlike the configuration described in Patent Literature 1, it is unnecessary to design the inspection regions 112. Therefore, it is possible to suppress a decrease in a portion for forming substrate regions (electronic component 200) in the sheet substrate 202.

However, in the configuration disclosed in Patent Literature 2, the inspection electrodes 210 remain in the electronic component 200 even after the division of the sheet substrate 202. Therefore, the inspection electrodes 210 act as parasitic capacitance for the electronic elements 208 and adversely affect the characteristics of the electronic elements 208.

### SUMMARY

An advantage of some aspects of the invention is to provide a manufacturing method for an electronic component, an inspection method for an electronic component, a sheet substrate, an electronic component, and an electronic apparatus in which a decrease in a portion for forming electronic components on a sheet substrate is suppressed, a contact area of inspection electrodes on the electronic component side required by inspection probes is secured, and occurrence of parasitic capacitance for electronic elements arranged on the sheet substrate is reduced.

The invention can be implemented as the following application examples.

### Application Example 1

This application example is directed to a manufacturing method for an electronic component including: preparing a sheet substrate on which a first substrate region, a second substrate region arranged to be integrated with the first substrate region, two terminals arranged in the first substrate region, a first conductive pattern arranged in the first substrate region, a second conductive pattern arranged in the second substrate region, and a first wire that electrically connects one of the two terminals and the second conductive pattern are arranged; electrically connecting an electronic element to the two terminals; arranging a first lid body on the first conductive pattern and electrically connecting the first conductive pattern and the first lid body, arranging a second lid body on the second conductive pattern and electrically connecting the second conductive pattern and the second lid body, and measuring a signal from the electronic element via the second lid body; and separating the sheet substrate into the first substrate region and the second substrate region.

According to the method, in an input and output inspection for the electronic element after packaging, it is possible to use a lid body, which forms the upper surface of the electronic component, as an inspection electrode as well without providing the inspection electrode anew. The input and output inspection for the electronic element to be inspected can be performed using the second substrate region present around the first substrate region in which the electronic element is arranged, i.e., the second lid body electrically connected to the electronic element to be inspected. Therefore, a manufacturing method for an electronic device is realized in which a contact area of the inspection electrode on the electronic component side required by an inspection probe is secured, a decrease in a portion for forming the electronic component on the sheet substrate is suppressed, and occurrence of parasitic capacitance for the electronic element after the division of the sheet substrate is reduced.

### Application Example 2

This application example is directed to the manufacturing method for an electronic component described in the application example 1, wherein a second wire is further arranged on the sheet substrate and the second wire includes a path returning from the first substrate region to the first substrate region through the second substrate regions and electrically connects the other of the two terminals and the first conductive pattern, and the manufacturing method further includes measuring a signal from the electronic element via the first lid body and the second lid body.

According to the method, in an input and output inspection for the electronic element after packaging, it is possible to use a lid body, which forms the upper surface of the electronic component, as an inspection electrode as well without providing the inspection electrode anew. The input and output inspection for the electronic element to be inspected can be performed using the first lid body on which the electronic element is arranged and the second substrate region present around the first substrate region in which the electronic element is arranged, i.e., the second lid body electrically connected to the electronic element to be inspected. Therefore, a manufacturing method for an electronic device is realized in which a contact area of the inspection electrode on the electronic component side required by an inspection probe is secured, a decrease in a portion for forming the electronic component on the sheet substrate is suppressed, and occurrence of parasitic capacitance for the electronic element after the division of the sheet substrate is reduced.

### Application Example 3

This application example is directed to the manufacturing method for an electronic component described in the application example 1, which further includes arranging, after electrically connecting the electronic element to the two terminals, a second electronic element electrically connected to the electronic element in the first substrate region.

### Application Example 4

This application example is directed to the manufacturing method for an electronic component described in the application example 2, which further includes arranging, after electrically connecting the electronic element to the two terminals, a second electronic element electrically connected to the electronic element in the first substrate region.

According to the method, it is possible to package the second electronic element in only the first substrate region where the packaged electronic element can satisfactorily operate. Therefore, it is possible to prevent a loss of the second electronic element and suppress costs.

### Application Example 5

This application example is directed to an inspection method for an electronic component including a sheet substrate on which a first substrate region, a second substrate region arranged to be integrated with the first substrate region, two terminals arranged in the first substrate region, a first conductive pattern arranged in the first substrate region, a second conductive pattern arranged in the second substrate region, and a first wire that electrically connects one of the two terminals and the second conductive pattern are arranged, the inspection method including electrically connecting an electronic element to the two terminals, arranging a first lid body on the first conductive pattern and electrically connecting the first conductive pattern and the first lid body, arranging a second lid body on the second conductive pattern and electrically connecting the second conductive pattern and the second lid body, and performing an inspection of the electronic element via the second lid body.

Because of a reason same as the reason in the application example 1, an inspection method for an electronic device is realized in which a contact area of the inspection electrode on the electronic component side required by an inspection probe is secured, a decrease in a portion for forming the electronic component on the sheet substrate is suppressed, and occurrence of parasitic capacitance for the electronic element after the division of the sheet substrate is reduced.

### Application Example 6

This application example is directed to the inspection method for an electronic component described in the application example 5, wherein a second wire is further arranged on the sheet substrate and the second wire includes a path returning from the first substrate region to the first substrate region through the second substrate regions and electrically connects the other of the two terminals and the first conductive pattern, and the inspection method further includes performing the inspection of the electronic element via the first lid body and the second lid body.

Because of a reason same as the reason in the application example 2, an inspection method for an electronic device is realized in which a contact area of the inspection electrode on the electronic component side required by an inspection probe is secured, a decrease in a portion for forming the electronic component on the sheet substrate is suppressed, and occurrence of parasitic capacitance for the electronic element after the division of the sheet substrate is reduced.

### Application Example 7

This application example is directed to a sheet substrate including a first substrate region, a second substrate region integrated with the first substrate region, a first pad arranged in the first substrate region, a second pad arranged in the second substrate region, an annular first conductive pattern arranged in the first substrate region and surrounding the first pad, and an annular second conductive pattern arranged in the second substrate region and surrounding the second pad. The first pad includes two terminals and a first wire that electrically connects one of the two terminals and the second conductive pattern.

Because of a reason same as the reason in the application example 1, a sheet substrate is realized in which a contact area of the inspection electrode on the electronic component side required by an inspection probe is secured, a decrease in a portion for forming the electronic component on the sheet substrate is suppressed, and occurrence of parasitic capacitance for the electronic element after the division of the sheet substrate is reduced.

### Application Example 8

This application example is directed to the sheet substrate described in the application example 7, a second wire is further arranged on the sheet substrate and the second wire includes a path returning from the first substrate region to the first substrate region through the second substrate regions and electrically connects the other of the two terminals and the first conductive pattern.

Because of a reason same as the reason in the application example 2, a sheet substrate is realized in which a contact area of the inspection electrode on the electronic component side required by an inspection probe is secured, a decrease in a portion for forming the electronic component on the sheet substrate is suppressed, and occurrence of parasitic capacitance for the electronic element after the division of the sheet substrate is reduced.

### Application Example 9

This application example is directed to an electronic component in which an electronic element and a lid body are arranged in the first substrate region described in the application example 7.

Because of a reason same as the reason in the application example 1, an electronic component is realized in which a contact area of the inspection electrode on the electronic component side required by an inspection probe is secured, a decrease in a portion for forming the electronic component on the sheet substrate is suppressed, and occurrence of parasitic capacitance for the electronic element after the division of the sheet substrate is reduced.

### Application Example 10

This application example is directed to an electronic component in which an electronic element and a lid body are arranged in the first substrate region described in the application example 8.

Because of a reason same as the reason in the application example 2, an electronic component is realized in which a contact area of the inspection electrode on the electronic component side required by an inspection probe is secured, a decrease in a portion for forming the electronic component on the sheet substrate is suppressed, and occurrence of parasitic capacitance for the electronic element after the division of the sheet substrate is reduced.

### Application Example 11

This application example is directed to an electronic apparatus mounted with the electronic component described in the application example 9.

Because of a reason same as the reason in the application example 1, an electronic apparatus is realized in which a contact area of the inspection electrode on the electronic component side required by an inspection probe is secured, a decrease in a portion for forming the electronic component on the sheet substrate is suppressed, and occurrence of parasitic capacitance for the electronic element after the division of the sheet substrate is reduced.

### Application Example 12

This application example is directed to an electronic apparatus mounted with the electronic component described in the application example 10.

Because of a reason same as the reason in the application example 2, an electronic apparatus is realized in which a contact area of the inspection electrode on the electronic component side required by an inspection probe is secured, a decrease in a portion for forming the electronic component on the sheet substrate is suppressed, and occurrence of parasitic capacitance for the electronic element after the division of the sheet substrate is reduced.

### BRIEF DESCRIPTION OF THE DRAWINGS

The invention will be described with reference to the accompanying drawings, wherein like numbers reference like elements.

FIG. 1 is a plan view of an electronic component (before singulation) according to a first embodiment.

FIG. 2 is a sectional view taken along line A-A of FIG. 1.

FIG. 3 is a bottom view of the electronic component (before singulation) according to the first embodiment.

FIG. 4 is a sectional view of the electronic component (after singulation) according to the first embodiment and is a sectional view based on a line of a portion further on the left side than a step portion of line A-A of FIG. 1.

FIG. 5 is a sectional view of the electronic component (after singulation) according to the first embodiment and is a sectional view based on a line of a portion further on the right side than the step portion of line A-A of FIG. 1.

FIGS. 6A to 6C are diagrams showing a manufacturing process for the electronic component according to the first embodiment, wherein FIG. 6A shows a sheet substrate manufacturing process, FIG. 6B shows a packaging process for a piezoelectric resonator element, and FIG. 6C shows a packaging process for a lid and a piezoelectric resonator element inspection process.

FIGS. 7A and 7B are diagrams showing a manufacturing process for a sheet substrate according to the first embodiment, wherein FIG. 7A shows a sheet substrate dividing process and FIG. 7B shows the divided electronic components.

FIG. 8 is a diagram showing patterns of wires and a first path of an inspection process in the electronic component (before singulation) according to the first embodiment.

FIG. 9 is a diagram showing patterns of wires and a second path of the inspection process in the electronic component (before singulation) according to the first embodiment.

FIG. 10 is a diagram showing patterns of wires and a third path of the inspection process in the electronic component (before singulation) according to the first embodiment.

FIG. 11 is a diagram showing patterns of wires and a fourth path of the inspection process in the electronic component (before singulation) according to the first embodiment.

FIG. 12 is a diagram showing patterns of wires and a fifth path of the inspection process in the electronic component (before singulation) according to the first embodiment.

FIG. 13 is a diagram showing patterns of wires and a sixth path of the inspection process in the electronic component (before singulation) according to the first embodiment.

FIG. 14 is a plan view of an electronic component (before singulation) according to a second embodiment.

FIG. 15 is a sectional view taken along line A-A of FIG. 14.

FIG. 16 is a sectional view taken along line B-B of FIG. 14.

FIG. 17 is a bottom view of the electronic component (before singulation) according to the second embodiment.

FIG. 18 is a sectional view of the electronic component (after singulation) according to the second embodiment.

FIG. 19 is a diagram showing an inspection method for the electronic component (before singulation) according to the second embodiment.

FIG. 20 is a plan view of an electronic component (before singulation) according to a third embodiment.

FIG. 21 is a sectional view taken along line A-A of FIG. 20.

FIG. 22 is a bottom view of the electronic component (before singulation) according to the third embodiment.

FIG. 23 is a sectional view of the electronic component (after singulation) according to the third embodiment and is a sectional view based on a line of a portion further on the right side than a step portion of line A-A of FIG. 20.

FIGS. 24A to 24C are diagrams showing a manufacturing process for the electronic component according to the third embodiment, wherein FIG. 24A shows a sheet substrate manufacturing process, FIG. 24B shows a packaging process for a piezoelectric resonator element, and FIG. 24C shows a packaging process for a lid body and a piezoelectric resonator element inspection process.

FIGS. 25A and 25B are diagrams showing a manufacturing process for a sheet substrate according to the third embodiment, wherein FIG. 25A shows a sheet substrate dividing process and FIG. 25B shows the divided electronic components.

FIG. 26 is a diagram showing patterns of wires and a first path of an inspection process in the electronic component (before singulation) according to the third embodiment.

FIG. 27 is a diagram showing patterns of wires and a second path of the inspection process in the electronic component (before singulation) according to the third embodiment.

FIG. 28 is a diagram showing patterns of wires and a third path of the inspection process in the electronic component (before singulation) according to the third embodiment.

FIG. 29 is a diagram showing patterns of wires and a fourth path of the inspection process in the electronic component (before singulation) according to the third embodiment.

FIG. 30 is a diagram showing patterns of wires and a fifth path of the inspection process in the electronic component (before singulation) according to the third embodiment.

FIG. 31 is a diagram showing patterns of wires and a sixth path of the inspection process in the electronic component (before singulation) according to the third embodiment.

FIG. 32 is a plan view of an electronic component (before singulation) according to a fourth embodiment.

FIG. 33 is a sectional view taken along line A-A of FIG. 32.

FIG. 34 is a bottom view of the electronic component (before singulation) according to the fourth embodiment.

FIG. 35 is a sectional view of the electronic component (after singulation) according to the fourth embodiment.

FIG. 36 is a diagram showing an inspection method for the electronic component (before singulation) according to the fourth embodiment.

FIG. 37 shows a schematic diagram of an electronic apparatus (a portable terminal) mounted with an electronic component according to an embodiment.

FIG. 38 is a plan view of a sheet substrate described in Patent Literature 1.

FIG. 39 is a sectional view of an electronic component described in Patent Literature 2.

### DESCRIPTION OF EXEMPLARY EMBODIMENTS

The invention is explained in detail below with reference to embodiments shown in the figures. Components and types, combinations, shapes, relative arrangements, and the like are not meant to limit the scope of the invention only thereto but are mere explanation examples unless specifically described otherwise.

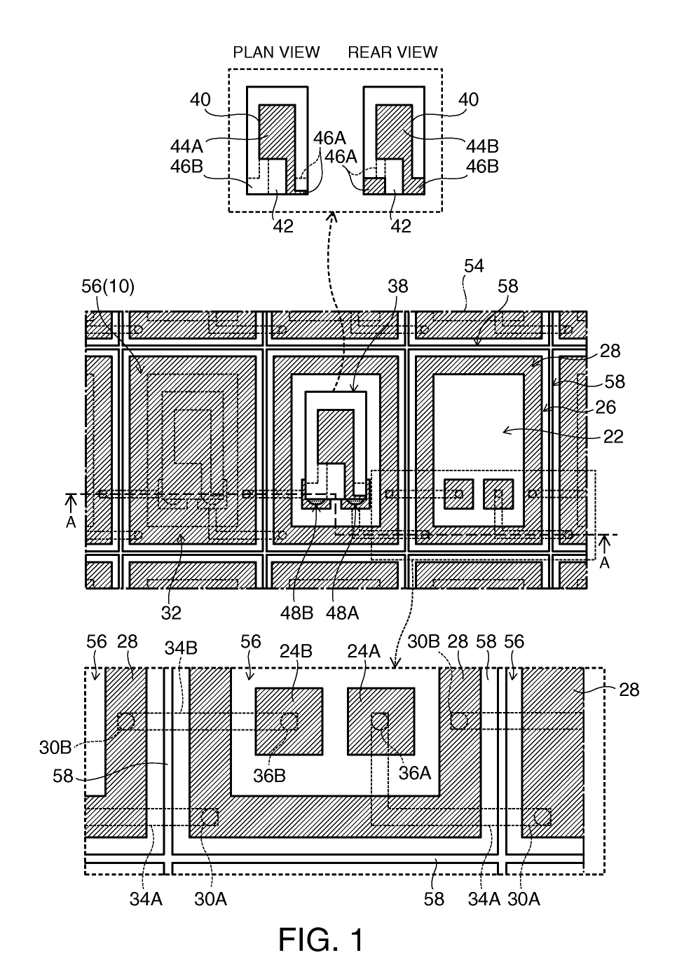

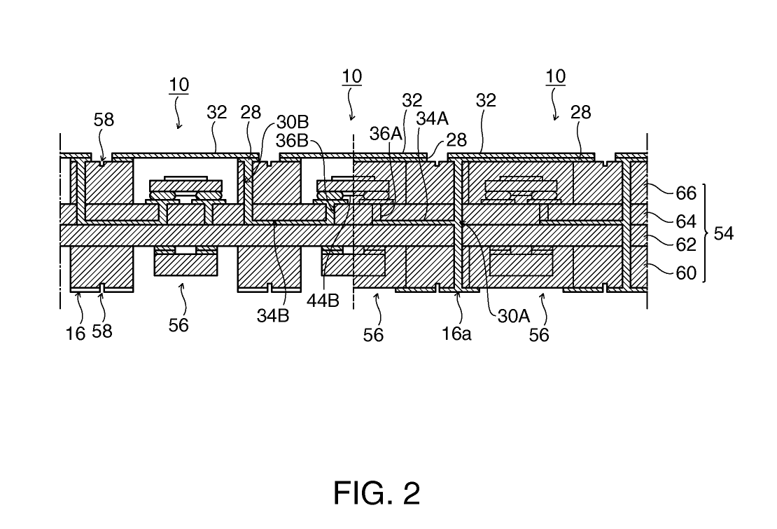

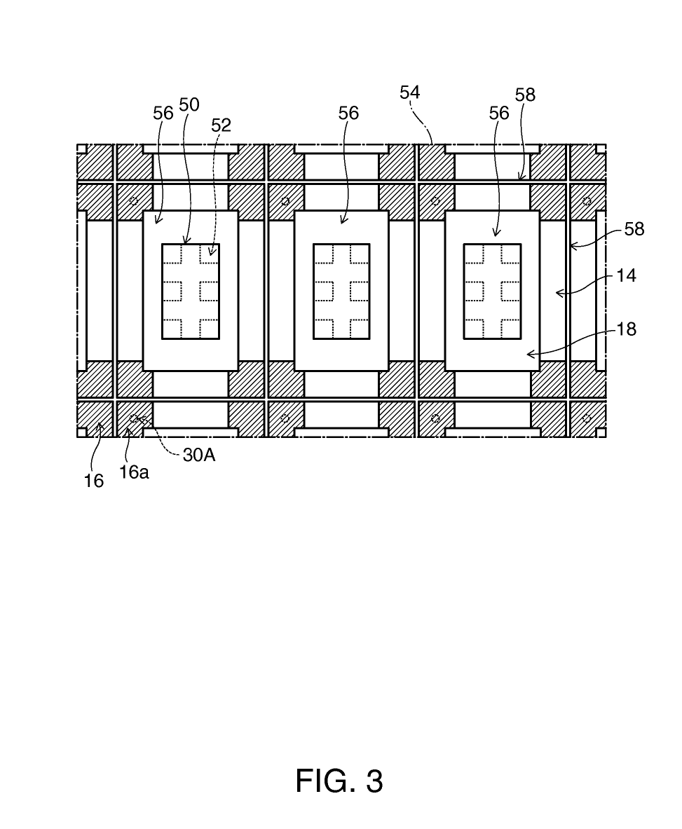

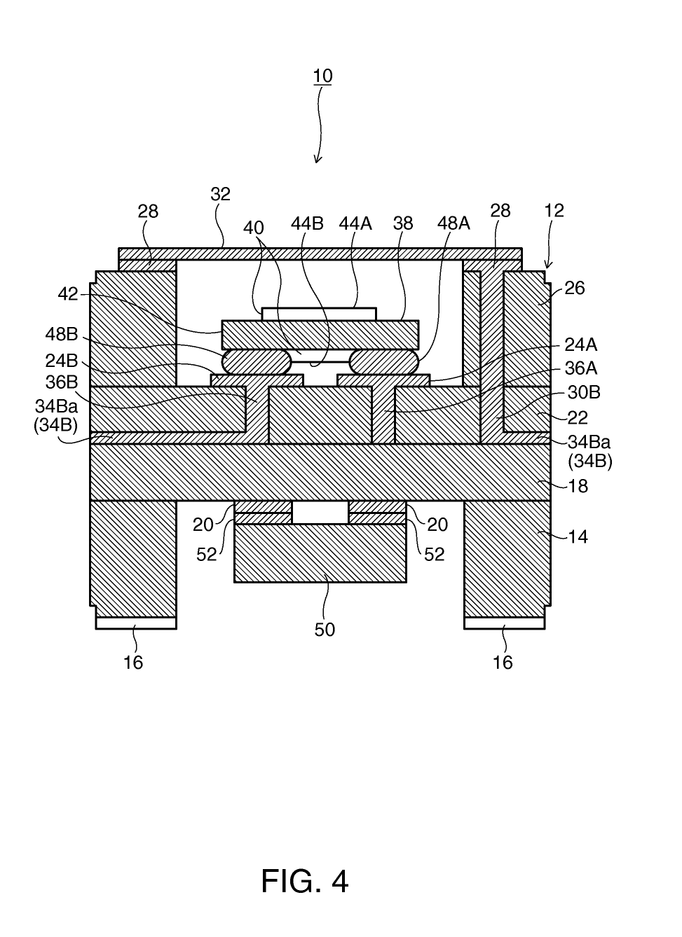

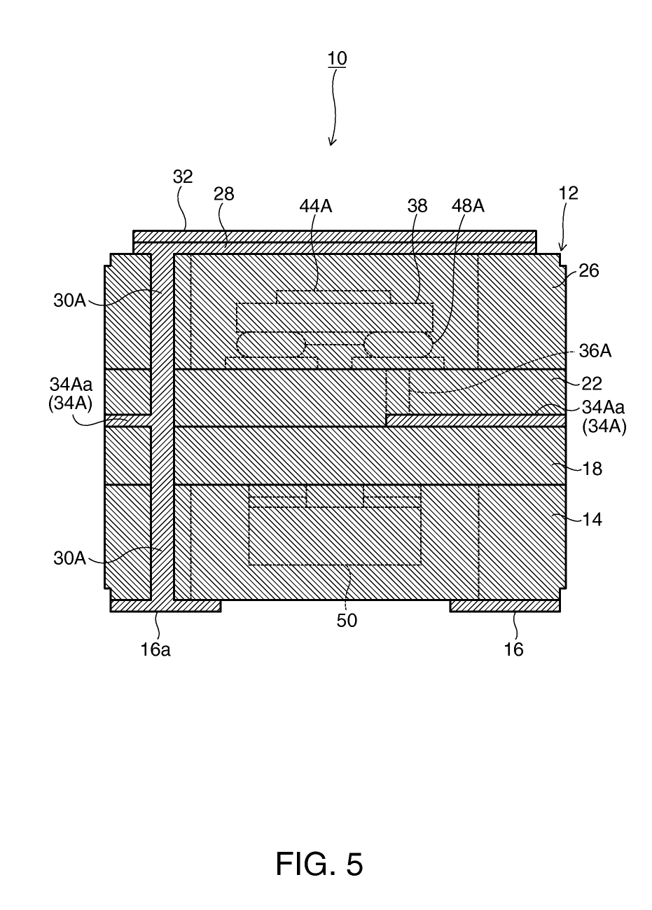

A plan view of an electronic component (before singulation) according to a first embodiment is shown in FIG. 1. A sectional view taken along line A-A of FIG. 1 is shown in FIG. 2. A bottom view of the electronic component (before singulation) according to the first embodiment is shown in FIG. 3. Sectional views of the electronic component (after singulation) according to the first embodiment, which are sectional views based on a line of a portion further on the left side and a line of a portion further on the right side than a step portion of line A-A of FIG. 1 are shown in FIGS. 4 and 5. To facilitate explanation, in FIG. 1, in an electronic component 10 drawn in the center, a lid 32 is not shown and, in the electronic component 10 drawn on the right side, the lid 32 and a piezoelectric resonator element 38 are not shown.

As explained in detail below, the electronic component 10 according to this embodiment is obtained by forming a plurality of the electronic components 10 in a collected state on a sheet substrate 54 and thereafter singulating the sheet substrate 54. In this embodiment, wires 34A and 34B (first wires) that can electrically connect a piezoelectric resonator element 38 packaged on the sheet substrate 54 to the lids 32 arranged in at least one (two in this embodiment) of substrate regions 56 (second substrate regions) present around the substrate region 56 (a first substrate region) in which the piezoelectric resonator element 38 is packaged are formed to extend across the substrate region (the first substrate region). An input and output inspection for the piezoelectric resonator element 38 is performed via the lids 32. The wires 34A and 34B are fragmented in the singulation. When the input and output inspection after the packaging of the piezoelectric resonator element 38 is performed, the substrate region 56 in which the piezoelectric resonator element 38 to be inspected is arranged is set as the first substrate region and the substrate regions 56 present around the first substrate region are set as the second substrate regions.

As shown in FIGS. 4 and 5, the electronic component 10 according to this embodiment is a piezoelectric device configured by a substrate 12 formed of an insulating material such as ceramic, the piezoelectric resonator element 38 (an electronic element), an integrated circuit 50 (a second electronic element) electrically connected to the piezoelectric resonator element 38, and the lid 32 (a lid body) having electrical conductivity such as metal. The piezoelectric device receives power supply from the outside to thereby oscillate by itself.

The substrate 12 forming the external shape of the electronic component 10 has a four-layer structure including a first frame-like substrate 14, a first center substrate 18, a second center substrate 22, and a second frame-like substrate 26 in order from the bottom. As shown in FIG. 4, the cross section of the substrate 12 is an H shape.

The first frame-like substrate 14 has a rectangular frame shape in plan view. The first frame-like substrate 14 is joined to the first center substrate 18 to thereby form a housing space for housing the integrated circuit 50. Packaged electrodes 16 are provided on the lower surface of the first frame-like substrate 14.

The integrated circuit 50 is packaged on the lower surface of the first center substrate 18. Connection electrodes 20 are provided in positions opposed to pad electrodes 52 of the integrated circuit 50.

The piezoelectric resonator element 38 is packaged on the upper surface of the second center substrate 22. Mount electrodes 24A and 24B (terminals) are arranged in positions joined to the piezoelectric resonator element 38. The mount electrodes 24A and 24B are electrically connected to a part of the connection electrodes 20 via through-electrodes (not shown in the figure) that pierce through the first center substrate 18 and the second center substrate 22. Therefore, the piezoelectric resonator element 38 and the integrated circuit 50 are electrically connected.

The second frame-like substrate 26 has a rectangular frame shape in plan view. The second frame-like substrate 26 is joined to the second center substrate 22 to thereby form a housing space for housing the piezoelectric resonator element 38. A metallization 28 (a conductive pattern) having a frame shape is provided on the upper surface of the second frame-like substrate 26. The lid 32 is joined to the metallization 28. The metallization 28 is electrically connected to the packaged electrode 16(16a) via a through-electrode 30A (FIG. 5) that pierces through the second frame-like substrate 26, the second center substrate 22, the first center substrate 18, and the first frame-like substrate 14.

The lid 32 is joined to the metallization 28 present around an opening of the second frame-like substrate 26 to seal the opening. Therefore, it is possible to seal the piezoelectric resonator element 38 in a vacuum by joining the lid 32 to the metallization 28 under a vacuum environment. On the other hand, it is possible to earth the lid 32 joined to the metallization 28 by earthing the packaged electrode 16 (16a). The connection electrodes 20 connected to the pad electrodes 52 for earthing of the integrated circuit 50 are electrically connected to the through-electrode 30A.

In this embodiment, the wires 34A and 34B exposed to the side surfaces of the substrate 12 are provided on the second center substrate 22 (or the first center substrate 18). As shown in FIGS. 4 and 5, a wire 34Aa is formed in a position opposed to the mount electrode 24A on the lower surface of the second center substrate 22 and is electrically connected to the mount electrode 24A via a through-electrode 36A. The wire 34Aa extends to the side surface of the substrate 12. The wire 34Aa is the wire 34A on the sheet substrate 54 before singulation as explained below.

Similarly, a wire 34Ba is formed in a position opposed to the mount electrode 24B and is electrically connected to the mount electrode 24B via a through-electrode 36B. The wire 34Ba extends in a direction opposite to the direction of the wire 34Aa to the side surface of the substrate 12. The wire 34Ba is the wire 34B on the sheet substrate 54 before singulation as explained below.

As shown in FIGS. 1 and 4, the piezoelectric resonator element 38 is formed of a piezoelectric material such as quartz. In this embodiment, the piezoelectric resonator element 38 is, for example, a thickness-shear resonator element including an AT cut substrate of quartz. The piezoelectric resonator element 38 includes a vibrating section 40 that performs thickness-slip vibration and a mount section 42 joined to the second center substrate 22. An exciting electrode 44A is arranged on the upper surface of the vibrating section 40. An exciting electrode 44B is arranged on the lower surface of the vibrating section 40. An extracting electrode 46A (FIG. 1) is drawn out from the exciting electrode 44A. An extracting electrode 46B (FIG. 1) is drawn out from the exciting electrode 44B. The extracting electrode 46A is drawn out to the lower surface of the mount section 42. The extracting electrode 46B is drawn out to the lower surface of the mount section 42 through the upper surface and the side surface of the mount section 42.

The extracting electrodes 46A and 46B and the mount electrodes 24A and 24B are joined by conductive adhesives 48A and 48B to join the mount section 42 to the second center substrate 22. Consequently, the piezoelectric resonator element 38 is supported on the substrate 12 in a cantilevered state and electrically connected to the integrated circuit 50. As the piezoelectric resonator element 38, besides the above, a tuning fork type resonator element, a dual tuning fork type resonator element, a SAW resonator element, and a gyro resonator element can be applied.

The integrated circuit 50 is obtained by integrally forming an oscillating circuit driven by the piezoelectric resonator element 38 functioning as an oscillation source, a temperature compensating circuit that performs temperature compensation for an oscillation signal, and the like. The pad electrodes 52 are arranged on an active surface (the upper surface) of the integrated circuit 50. As the pad electrodes 52, there are connection terminals (X1 and X2) electrically connected to the piezoelectric resonator element 38. The pad electrodes 52 are respectively electrically connected to the mount electrodes 24A and 24B via through-electrodes (not shown in the figure). The pad electrodes 52 are a power supply terminal (Vcc) that receives power supply from the outside, a ground terminal (GND), an output terminal (O/P) for an oscillation signal, and a terminal for adjustment for performing writing of a program. The pad electrodes 52 are respectively electrically connected to the packaged electrodes 16. The ground terminal (GND) is electrically connected to the packaged electrodes 16(16a). Therefore, the number of the packaged electrodes 16 is designed according to the number of pad electrodes 52 of the integrated circuit 50.

As shown in FIGS. 1 to 3, the sheet substrate 54 is a member before singulation of the substrate 12 of the electronic component 10. On the sheet substrate 54, the substrate regions 56, each of which is a portion for forming one electronic component 10, are sectioned in a matrix shape. Dividing grooves 58 for dividing the sheet substrate 54 are formed in boundaries among the substrate regions 56.

As shown in FIG. 2, the sheet substrate 54 has a four-layer structure including a first sheet substrate 60, a second sheet substrate 62, a third sheet substrate 64, and a fourth sheet substrate 66 in order from the bottom.

The first sheet substrate 60 is a member before singulation of the first frame-like substrates 14. The first sheet substrate 60 has a form in which the first frame-like substrates 14 are collected in a matrix shape. The dividing grooves 58 for dividing the sheet substrate 54 are formed on the lower surface of the first sheet substrate 60.

The second sheet substrate 62 is a member before singulation of the first center substrates 18. The second sheet substrate 62 has a form in which the first center substrates 18 are collected in a matrix shape. The third sheet substrate 64 is a member before singulation of the second center substrates 22. The third sheet substrate 64 has a form in which the second center substrates 22 are collected in a matrix shape.

The fourth sheet substrate 66 is a member before singulation of the second frame-like substrates 26. The fourth sheet substrate 66 has a form in which the second frame-like substrates 26 are collected in a matrix shape. The dividing grooves 58 for dividing the sheet substrate 54 are formed on the upper surface of the fourth sheet substrate 66.

As shown in FIGS. 1 and 2, the wires 34A and 34B electrically connected to the mount electrodes 24A and 24B via the through-electrodes 36A and 36B are arranged on the third sheet substrate 64 (or the second sheet substrate 62).

The wire 34A electrically connected to the mount electrode 24A extends to the right side from a position right under the mount electrode 24A. The wire 34A extends from the substrate region 56, which includes the mount electrodes 24A, to a position of the substrate region 56 on the right side of the dividing groove 58, where the metallization 28 is arranged, across the dividing groove 58. The wire 34A is electrically connected to the metallization 28 via the through-electrode 30A.

The wire 34B electrically connected to the mount electrode 24B extends to the left side from a position right under the mount electrode 24B. The wire 34B extends from the substrate region 56, which includes the mount electrode 24B, to a position of the substrate region 56 on the left side of the dividing groove 58, where the metallization 28 is arranged, across the dividing groove 58. The wire 34B is electrically connected to the metallization 28 via a through-electrode 30B.

In this embodiment, the wires 34A and 34B extend in the opposite directions from each other and across the boundaries (the dividing grooves 58) between the adjacent substrate regions 56. The wires 34A and 34B electrically connect the piezoelectric resonator element 38 arranged in the substrate region 56 (the first substrate region) and the lids 32 arranged in at least one (two in this embodiment) among the substrate regions 56 (the second substrate regions) present around the substrate region 56 in which the piezoelectric resonator element 38 is arranged.

As shown in FIG. 2, the exciting electrode 44A of the piezoelectric resonator element 38 drawn in the center is electrically connected to the lid 32 of the substrate region 56 (the electronic component 10) on the right side via the extracting electrode 46A (FIG. 1), the conductive adhesive 48A, the mount electrode 24A, the through-electrode 36A, the wire 34A, and the through-electrode 30A. Similarly, the exciting electrode 44B is electrically connected to the lid 32 of the substrate region 56 (the electronic component 10) on the left side via the extracting electrode 46B (FIG. 1), the conductive adhesive 48B, the mount electrode 24B, the through-electrode 36B, the wire 34B, and the through-electrode 30B.

In this embodiment, before the sheet substrate 54 is divided, the piezoelectric resonator elements 38 arranged in the respective substrate regions 56 (the first substrate regions) are electrically connected to the lids 32 arranged in the substrate regions 56 (the second substrate regions) on both the sides of the substrate regions 56 (the first substrate regions). That is, in an input and output inspection for the piezoelectric resonator element 38 after being packaged on the sheet substrate 54, it is possible to use the lids 32, which form the upper surface of the electronic component 10, as inspection electrodes as well without providing the inspection electrodes anew. Therefore, it is possible to secure a contact area of the inspection electrodes on the electronic component 10 side required by the inspection probe 68 explained below and suppress a decrease in a portion for forming the substrate regions 56 (the electronic component 10) on the sheet substrate 54.

On the other hand, the wires 34A and 34B are fragmented by dividing the sheet substrate 54 along the dividing grooves 58. The piezoelectric resonator element 38 can be electrically connected to only the integrated circuit 50 arranged in the same substrate region 56 (first substrate region). Since the lids 32 after the division of the sheet substrate 54 are earthed, parasitic capacitance is not caused for the piezoelectric resonator element 38. Therefore, the sheet substrate 54 and the electronic component 10 are realized in which occurrence of parasitic capacitance for the piezoelectric resonator element 38 after the division of the sheet substrate 54 is reduced.

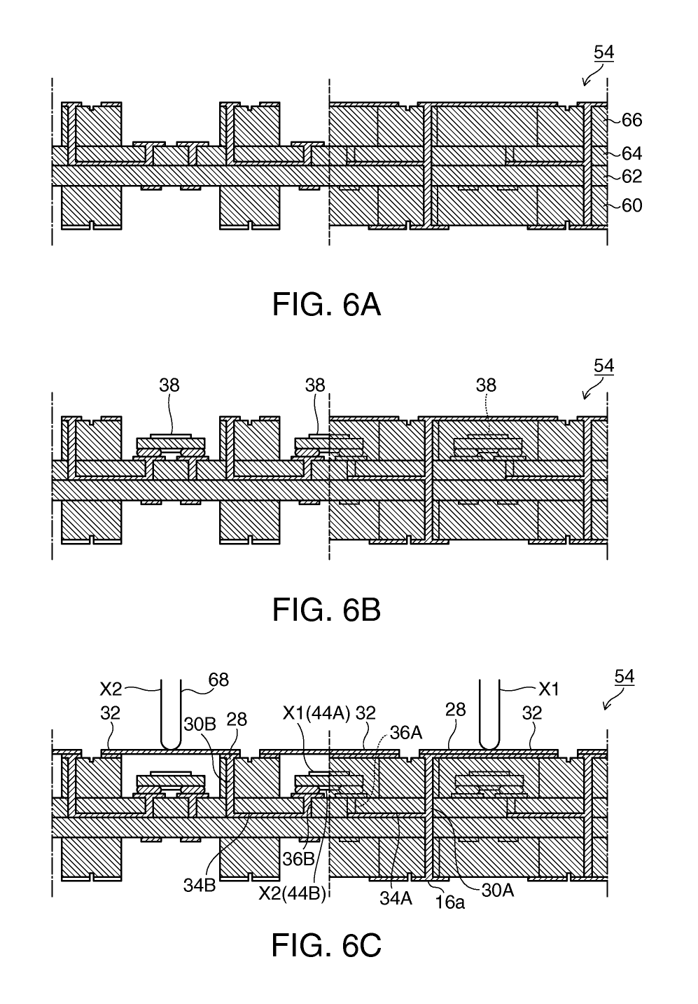

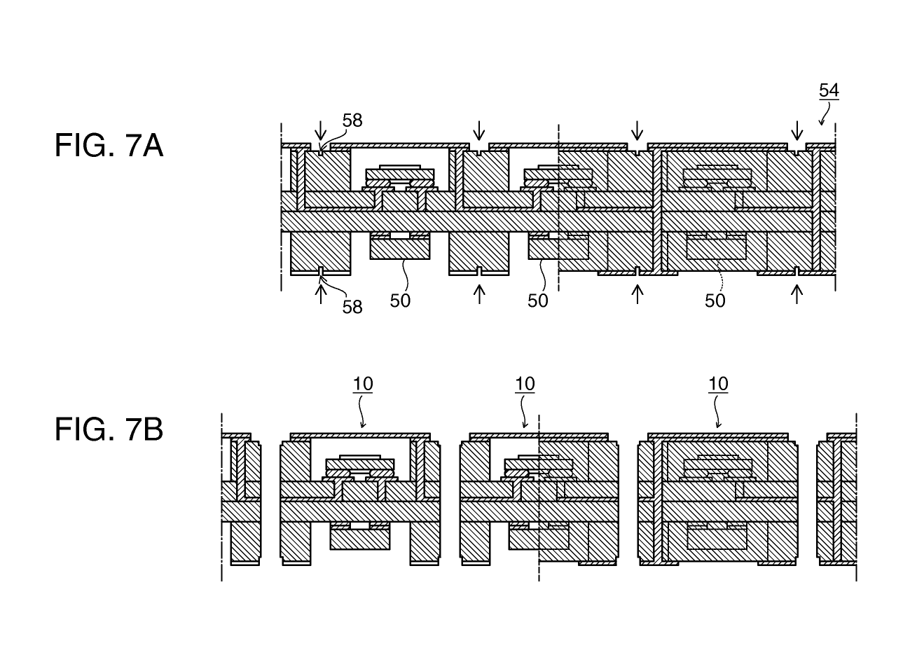

A manufacturing process for the electronic component according to the first embodiment is explained. The manufacturing process for the electronic component according to the first embodiment is shown in FIGS. 6A to 6C and FIGS. 7A and 7B.

As shown in FIG. 6A, the first sheet substrate 60, the second sheet substrate 62, the third sheet substrate 64, and the fourth sheet substrate 66 are formed and are laminated to form the sheet substrate 54.

As shown in FIG. 6B, the piezoelectric resonator elements 38 are packaged in the respective substrate regions 56. As shown in FIG. 6C, the lids 32 are joined in the respective substrate regions 56. The inspection probes 68 are brought into contact with the lids 32 of the substrate regions 56 (the second substrate regions) present on both the sides of the substrate region 56 (the first substrate region) in which the piezoelectric resonator element 38 to be inspected is packaged. When an input and output inspection for the piezoelectric resonator element 38 is performed using the inspection probes 68, it is possible to specify an inoperable piezoelectric resonator element 38 or, even when the piezoelectric resonator element 38 operates, specify the piezoelectric resonator element 38, a resonance frequency and a CI value of which deviate from allowable ranges.

In the manufacturing process in this embodiment, identification inspection information in which position information of the inspection probes 68 and acceptance and rejection by an inspection of the piezoelectric resonator element 38 are associated with each other is generated. A manipulator (not shown in the figures) attached with the integrated circuit 50 is actuated on the basis of the identification inspection information. The integrated circuit 50 is not packaged in the substrate region 56 including the piezoelectric resonator element 38 rejected on the basis of the identification inspection information. The integrated circuit 50 is packaged in only the substrate region 56 in which the packaged piezoelectric resonator element 38 satisfactorily operates. Consequently, it is possible to prevent a loss of the integrated circuit 50 and suppress costs.

Blades (not shown in the figures) are pressed against the sheet substrate 54 along the dividing grooves 58 of the sheet substrate 54 as shown in FIG. 7A, whereby the electronic component 10 is singulated as shown in FIG. 7B. According to the singulation, the wires 34A and 34B are fragmented in the dividing grooves 58 set as boundaries. However, the wires 34Aa (FIG. 5) and 34Ba (FIG. 4) remain in the electronic component 10.

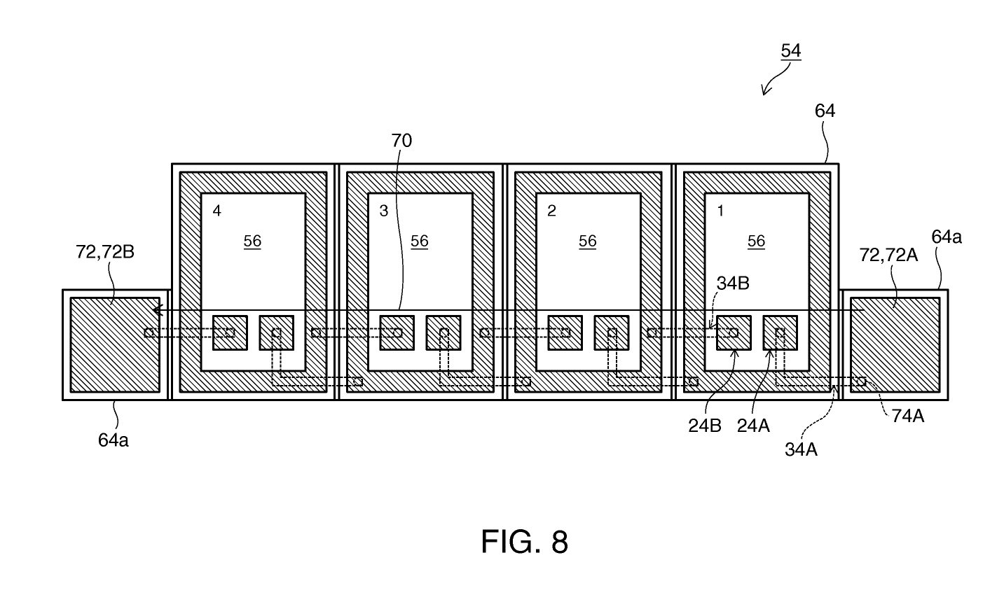

In FIGS. 8 to 13, patterns of wires and paths of an inspection process in the electronic component (before singulation) according to the first embodiment are shown. In FIGS. 8 to 13, the lids 32 and the piezoelectric resonator elements 38 are not shown.

When an inspection of the electronic component 10 is performed, a path 70 that alternately passes the boundaries of the substrate regions 56, across which the wires 34A and 34B extend, and the substrate regions 56, in which the wires 34A and 34B are arranged, is in a direction in which the inspection probes 68 are moved from the substrate region 56 to be inspected to the substrate region 56 to be inspected next. In the path 70, when the piezoelectric resonator element 38 in a kth (k is a positive integer) substrate region 56 that the path 70 passes is inspected, the inspection probes 68 are brought into contact with a (k−1)th lid 32 and a (k+1)th lid 32. However, the substrate region 56 (the lid 32) to which one of the wires 34A and 34B is connected is absent in the substrate regions 56 at the start end and the terminal end of the path 70.

Therefore, as shown in FIG. 8, it is necessary to separately provide inspection electrodes 72 (72A and 72B). For example, in the third sheet substrate 64 (or the second sheet substrate 62) on which the wires 34A and 34B are arranged, inspection substrates 64a are left in positions adjacent to the substrate regions 56 at the start end and the terminal end of the path 70. The inspection electrodes 72A and 72B are formed on the upper surfaces of the inspection substrates 64a. The wires 34A and 34B are extended to the lower surfaces of the inspection substrates 64a. The inspection electrodes 72A and 72B and the wires 34A and 34B only have to be electrically connected to each other via through-electrodes 74A and 74B that pierce through the inspection substrates 64a.

As shown in FIG. 8, in an inspection from the right to the left, when the inspection of the piezoelectric resonator element 38 in the first substrate region 56 is performed, the inspection probes 68 only have to be brought into contact with the inspection electrode 72A on the right and the lid 32 of the second substrate region 56. When the inspection of the piezoelectric resonator element 38 in the fourth (last) substrate region 56 is performed, the inspection probes 68 only have to be brought into contact with the inspection electrode 72B on the left and the lid 32 of the third substrate region 56.

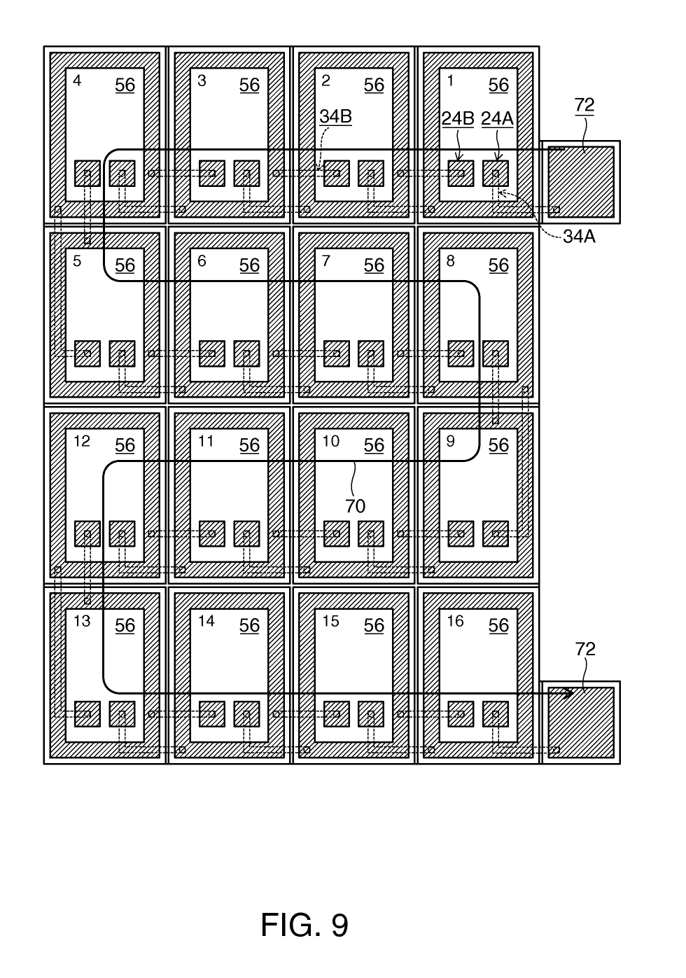

FIG. 8 shows the substrate regions 56 (the electronic component 10) arranged in a lateral row on the sheet substrate 54. When the substrate regions 56 are arranged in a matrix shape on the sheet substrate 54, in the patterns of the wires 34A and 34B, the inspection electrodes 72A and 72B need to be prepared at both ends of the respective rows. A portion for forming the substrate regions 56 (the electronic component 10) on the sheet substrate 54 decreases. Therefore, as shown in FIGS. 9 to 13, when the substrate regions 56 (the electronic component 10) are sectioned in a matrix shape (4×4=16) on the sheet substrate 54, the patterns of the wires 34A and 34B are devised.

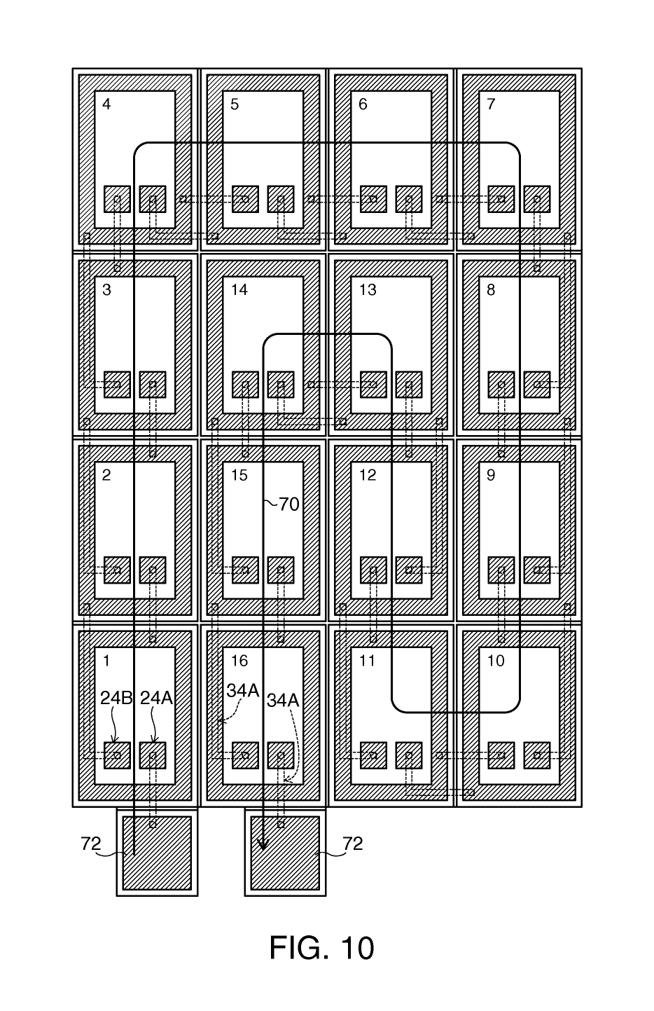

In FIGS. 9 and 10, not only the pattern for respectively extending the wires to the substrate regions 56 on both the sides in the lateral direction as explained above, the pattern for respectively extending the wires to the substrate regions 56 on both the sides in the lateral direction and a pattern for extending one of the wires to the substrate regions 56 adjacent to each other in the lateral direction and extending the other to the substrate regions 56 adjacent to each other in the longitudinal direction are combined to build the path 70 that passes all the substrate regions 56 in one-stroke sketch. In FIGS. 9 and 10, the last substrate region 56 to be inspected is present adjacent to the first substrate region 56 to be inspected.

Consequently, only two inspection electrodes 72 have to be provided. The inspection electrodes 72 are provided only on one side of the sheet substrate 54. Therefore, it is possible to suppress a decrease in a portion for forming the sheet substrate 54.

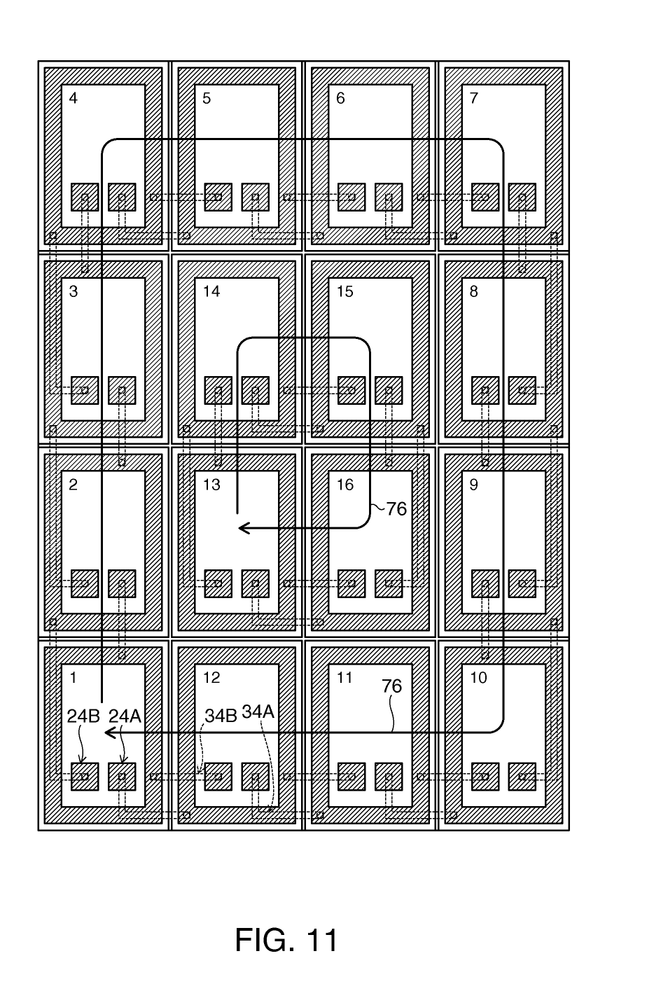

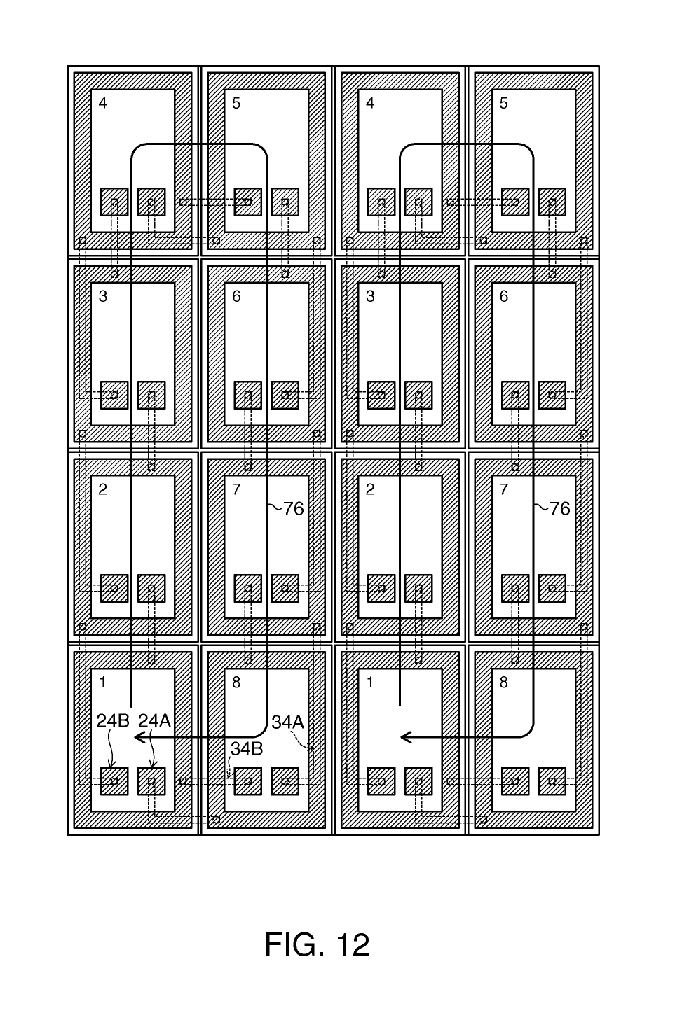

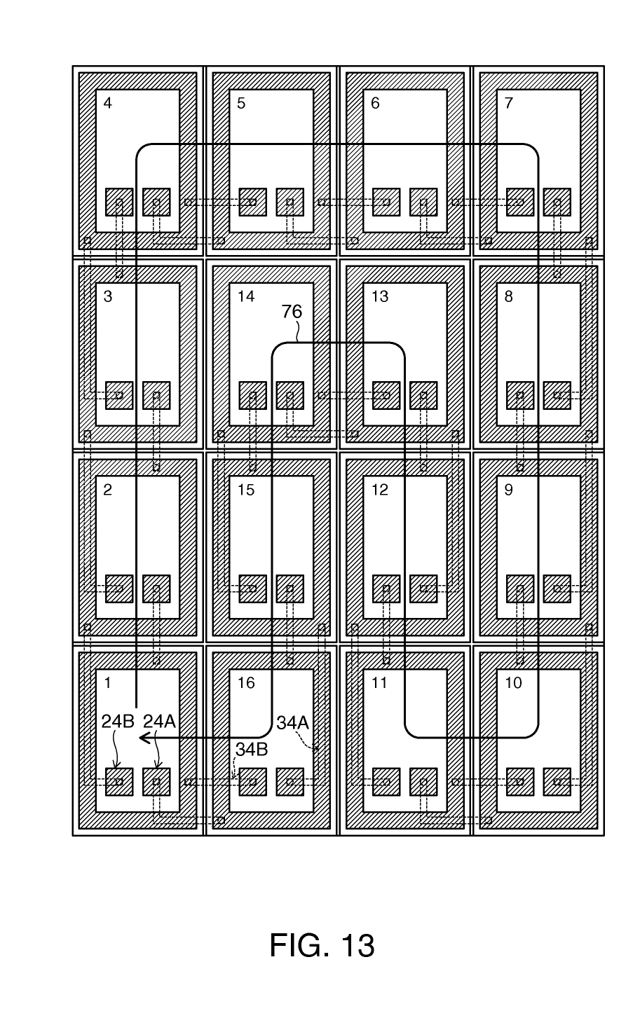

In FIGS. 11 to 13, the three patterns explained above are used to build a path 76 circulating through the substrate regions 56. In FIG. 11, the path 76 circulating through the substrate regions 56 forming the peripheral edge of the sheet substrate 54 and the path 76 circulating on the inner side of the substrate regions 56 are built. All the substrate regions 56 are covered by the two paths 76. In FIG. 12, all the substrate regions 56 are covered by the two paths 76 in a form in which the paths 76 circulating through the substrate regions 56 are arranged side by side. In FIG. 13, the path 76 not only circulating through the substrate regions 56 but also passing through the substrate regions 56 in one-stroke sketch to cover all the substrate regions 56 is built. By building the paths 76 shown in FIGS. 11 to 13, the inspection electrodes 72 are made unnecessary. It is possible to prevent a decrease in a portion for forming the sheet substrate 54.

In FIG. 11, when the inspection of the piezoelectric resonator element 38 in the first substrate region 56 is performed, the inspection probes 68 only have to be brought into contact with the lids 32 of the twelfth and second substrate regions 56. When the inspection of the piezoelectric resonator element 38 in the twelfth substrate region 56 is performed, the inspection probes 68 only have to be brought into contact with the lids 32 of the eleventh and first substrate regions 56. When the inspection of the piezoelectric resonator element 38 in the thirteenth substrate region 56 is performed, the inspection probes 68 only have to be brought into contact with the lids 32 of the sixteenth and fourteenth substrate regions 56. When the inspection of the piezoelectric resonator element 38 in the sixteenth substrate region 56 is performed, the inspection probes 68 only have to be brought into contact with the lids 32 of the fifteenth and thirteenth substrate regions 56.

In FIG. 12, when the inspection of the piezoelectric resonator element 38 in the first substrate region 56 is performed, the inspection probes 68 only have to be brought into contact with the lids 32 of the eighth and second substrate regions 56. When the inspection of the piezoelectric resonator element 38 in the eighth substrate region 56 is performed, the inspection probes 68 only have to be brought into contact with the lids 32 of the seventh and first substrate regions 56.

In FIG. 13, when the inspection of the piezoelectric resonator element 38 in the first substrate region 56 is performed, the inspection probes 68 only have to be brought into contact with the lids 32 of the sixteenth and second substrate regions 56. When the inspection of the piezoelectric resonator element 38 in the sixteenth substrate region 56 is performed, the inspection probes 68 only have to be brought into contact with the lids 32 of the fifteenth and first substrate regions 56.

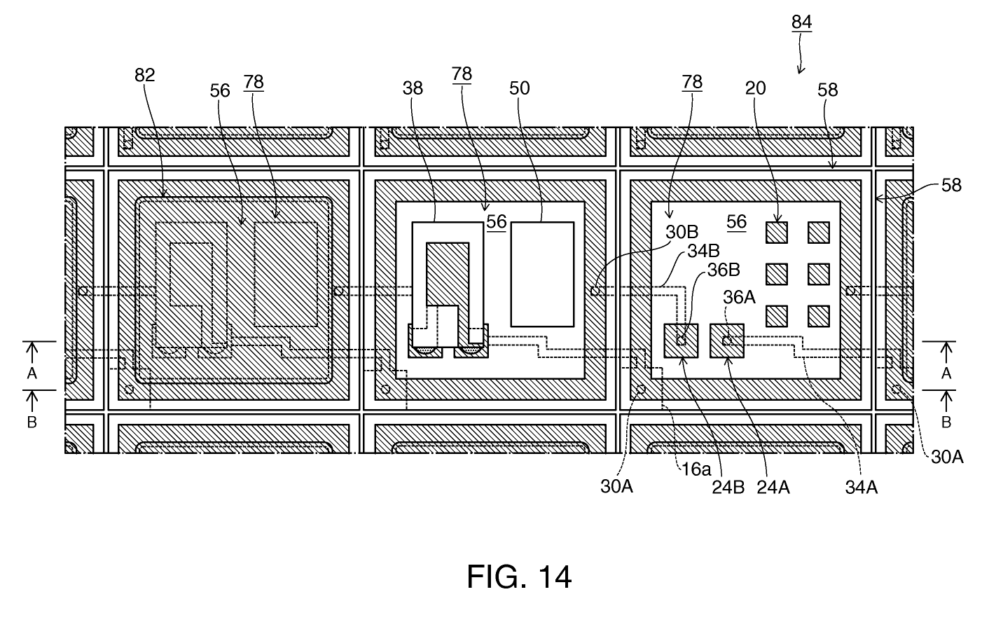

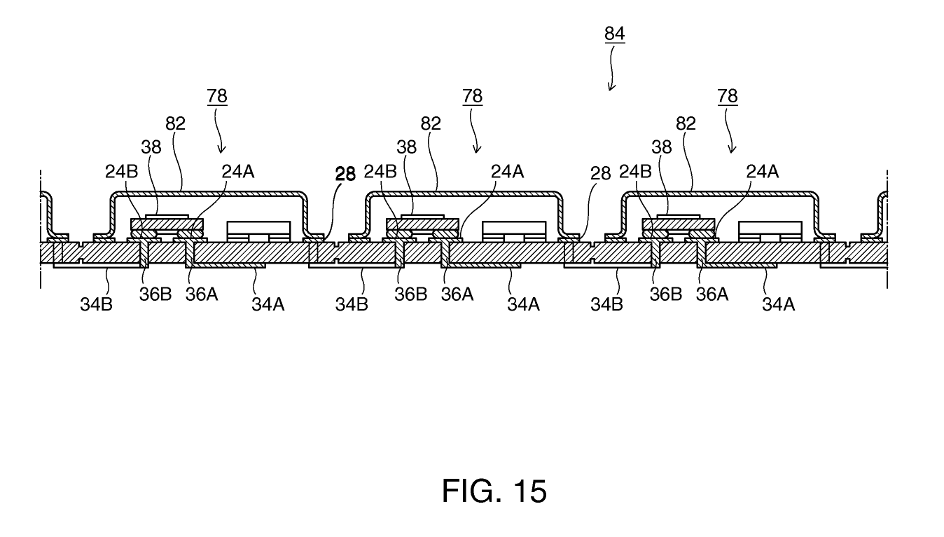

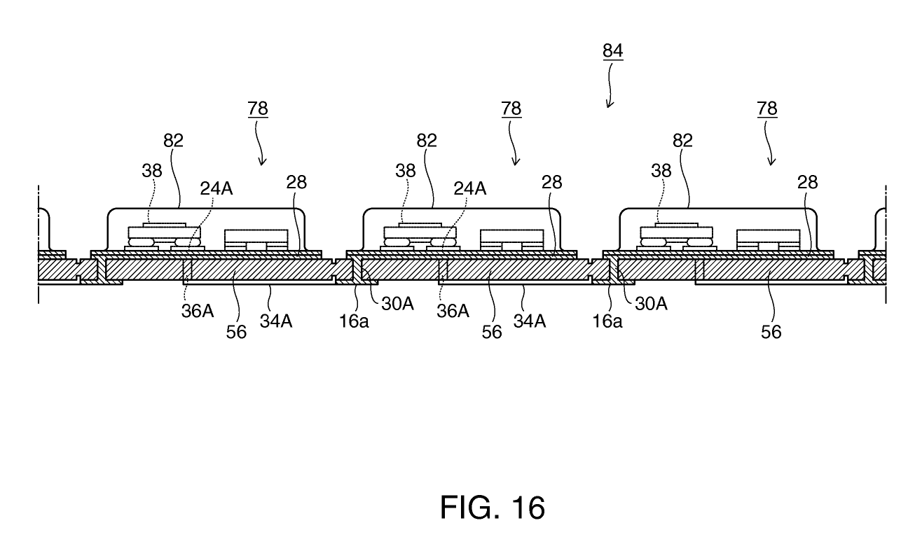

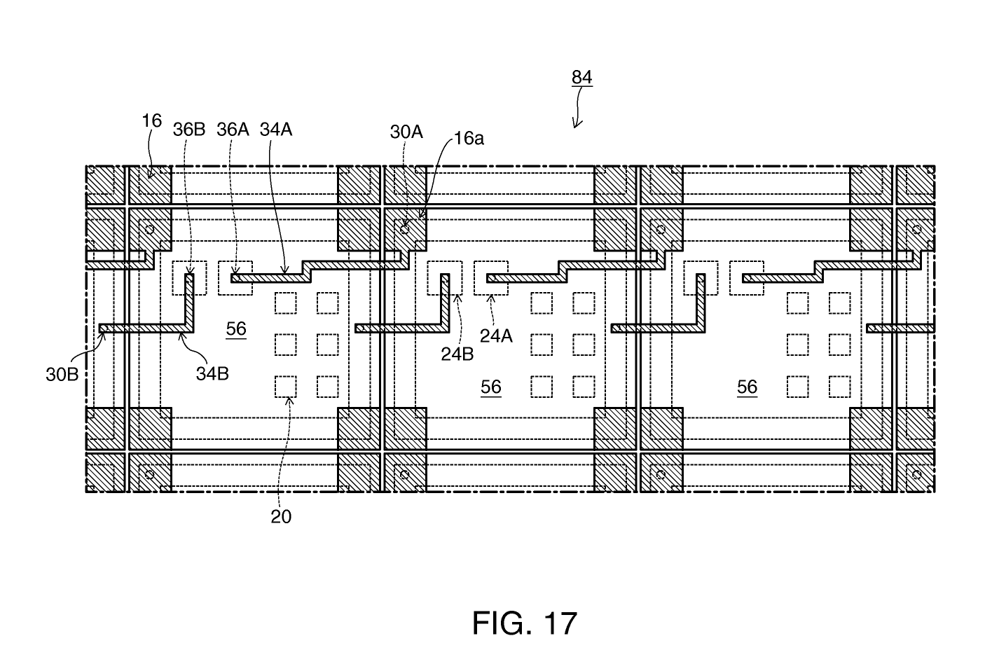

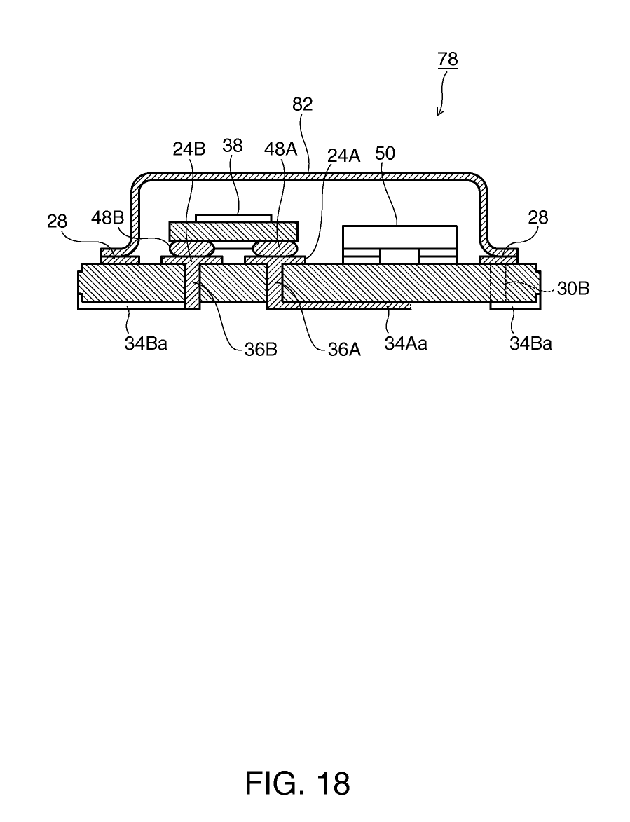

A plan view of an electronic component (before singulation) according to a second embodiment is shown in FIG. 14. A sectional view taken along line A-A of FIG. 14 is shown in FIG. 15. A sectional view taken along line B-B of FIG. 14 is shown in FIG. 16. A bottom view of the electronic component (before singulation) according to the second embodiment is shown in FIG. 17. A sectional view of the electronic component (after singulation) according to the second embodiment is shown in FIG. 18. In the following explanation, components common to the first embodiment are denoted by the same reference numerals and signs. Explanation of the components is omitted except when necessary.

As shown in FIG. 18, in an electronic component 78 according to the second embodiment, the piezoelectric resonator element 38 and the integrated circuit 50 are arranged on the same surface of a substrate 80. The piezoelectric resonator element 38 and the integrated circuit 50 are sealed by a cap 82 (a lid body). The cap 82 is formed by a conductive member such as metal. The cap 82 has a housing space for housing the piezoelectric resonator element 38 and the integrated circuit 50 and hermetically seals the piezoelectric resonator element 38 and the integrated circuit 50.

As shown in FIGS. 14 to 17, a sheet substrate 84 used as a material of the substrate 80 is one sheet. The dividing grooves 58 forming the boundaries among the substrate regions 56 are provided on the upper surface and the lower surface of the sheet substrate 84. The mount electrodes 24A and 24B for packaging the piezoelectric resonator elements 38 and the connection electrodes 20 for packaging the integrated circuits 50 are arranged in the respective substrate regions 56 on the upper surface of the sheet substrate 84. In the respective substrate regions 56, the metallizations 28 joined to the lower surfaces of the caps 82 are arranged in positions around the piezoelectric resonator elements 38 and the integrated circuits 50.

The wires 34A and 34B respectively electrically connected to the mount electrodes 24A and 24B via the through-electrodes 36A and 36B are arranged in positions opposed to the mount electrodes 24A and 24B on the lower surface of the sheet substrate 84.

In FIGS. 14 and 17, the wire 34A extends to the right side from the position opposed to the mount electrode 24A. The wire 34A is connected to a packaged electrode 16a of the substrate region 56 (the second substrate region) on the right side across the boundary of the substrate region 56 (the first substrate region). The packaged electrode 16a is electrically connected to the metallization 28 via the through electrode 30A. On the other hand, the wire 34B extends to the left side from the position opposed to the mount electrode 24B and extends to a position opposed to the metallization 28 of the substrate region 56 (the second substrate region) on the left side across the boundary of the substrate region 56 (the first substrate region). The wire 34B is electrically connected to the metallization 28 (the cap 82) via the through-electrode 30B.

Therefore, the piezoelectric resonator element 38 in the substrate region 56 (the first substrate region) in the center shown in FIGS. 15 and 16 is electrically connected to the cap 82 arranged in the substrate region 56 (the second substrate region) on the left as shown in FIG. 15 and electrically connected to the cap 82 arranged in the substrate region 56 (the second substrate region) on the right side as shown in FIG. 16.

In a manufacturing process for the electronic component 78 in the second embodiment, after the piezoelectric resonator element 38 and the integrated circuit 50 are packaged on the sheet substrate 84, the cap 82 is joined to the sheet substrate 84. An inspection of the piezoelectric resonator element 38 to be inspected can also be performed by bringing the inspection probes 68 into contact with the caps 82 arranged in the substrate regions 56 (the second substrate regions) on both the sides of the substrate region 56 (the first substrate region) in which the piezoelectric resonator element 38 is packaged. However, when the piezoelectric resonator element 38 is rejected by the inspection, even if the integrated circuit packaged in the substrate region 56 in which the piezoelectric resonator element 38 is packaged normally operates, there is a loss of the integrated circuit 50. Therefore, the inspection is performed as explained below.

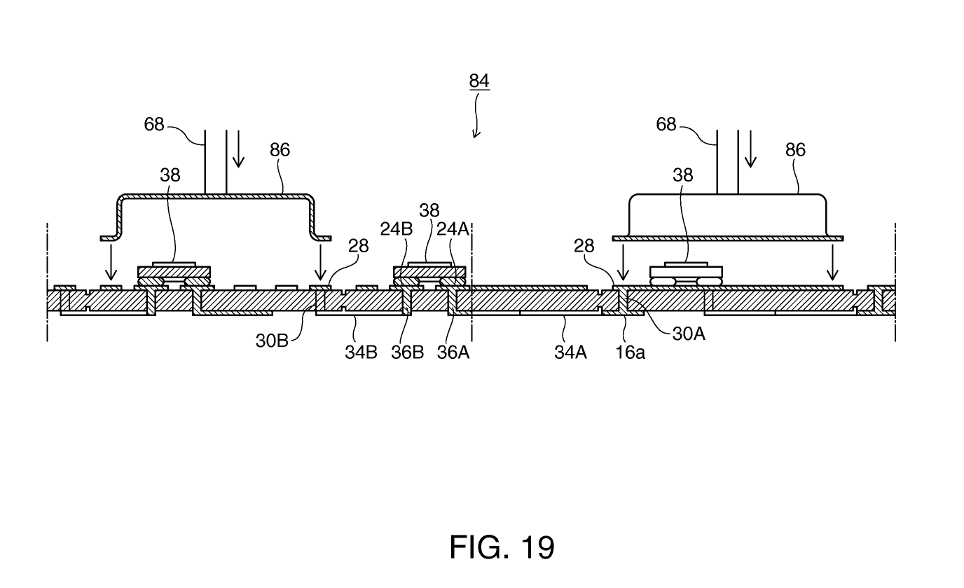

An inspection method for the electronic component (before singulation) according to the second embodiment is shown in FIG. 19. The left half of FIG. 19 on the left side of an alternate long and short dash line in the center is a sectional view taken along line A-A of FIG. 14. A state before attachment of the integrated circuit 50 and the cap 82 is shown in the left half. The right half is a sectional view taken along line B-B of FIG. 14. A state before the attachment of the integrated circuit 50 and the cap 82 is shown in the right half.

As shown in FIG. 19, the piezoelectric resonator elements 38 are packaged in the respective substrate regions 56 of the sheet substrate 84. For example, as shown in FIG. 19, inspection members 86 having the same shape as the caps 82 are attached to the tips of the inspection probes 68. The inspection members 86 are brought into contact with the metallizations 28 in the substrate regions 56 (the second substrate regions) on both the sides of the substrate region (the first substrate region) in which the piezoelectric resonator element 38 to be inspected is packaged. Consequently, it is possible to package the integrated circuit 50 only in the substrate region 56 in which the piezoelectric resonator element 38 accepted by the inspection is packaged and join the cap 82 to the substrate region 56. Therefore, it is possible to prevent a loss of the integrated circuit 50 and the cap 82.

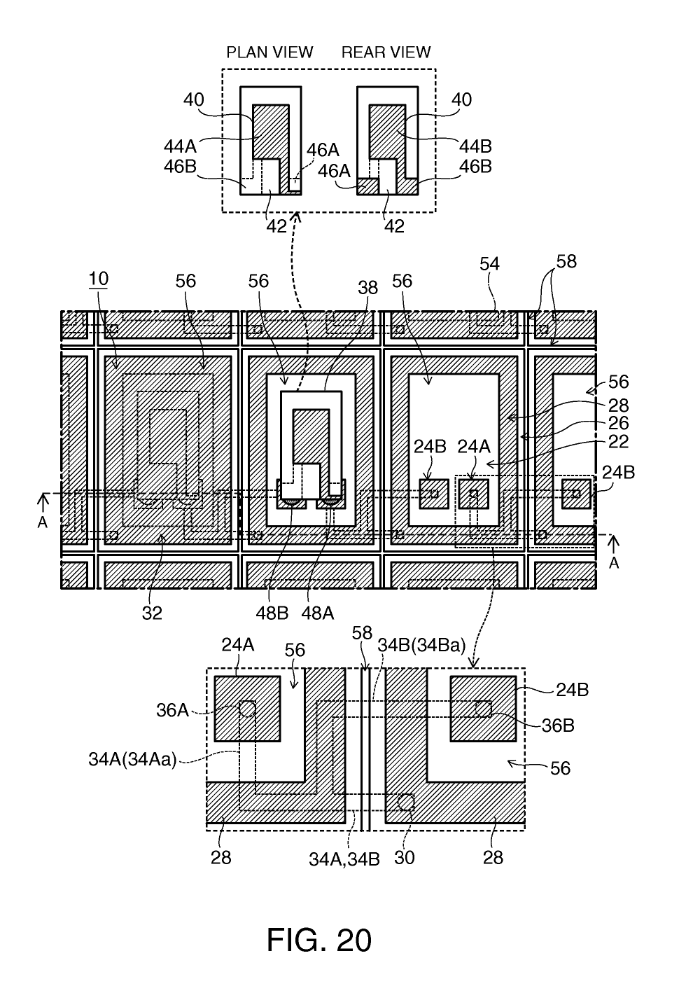

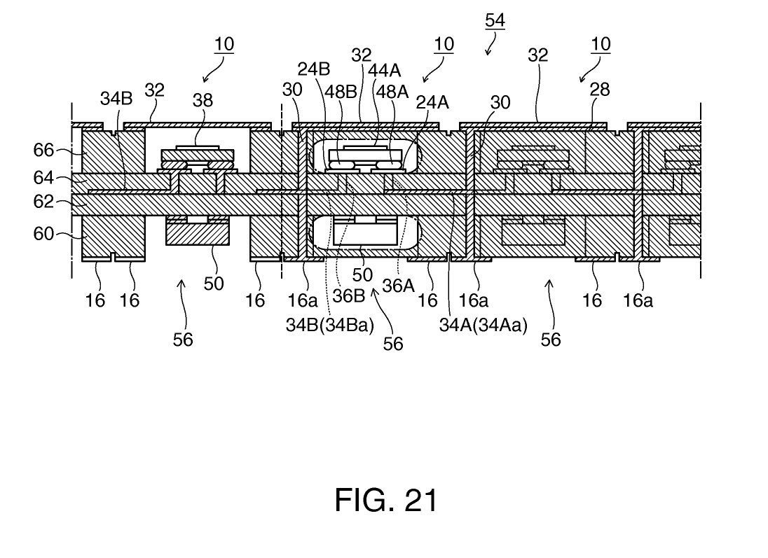

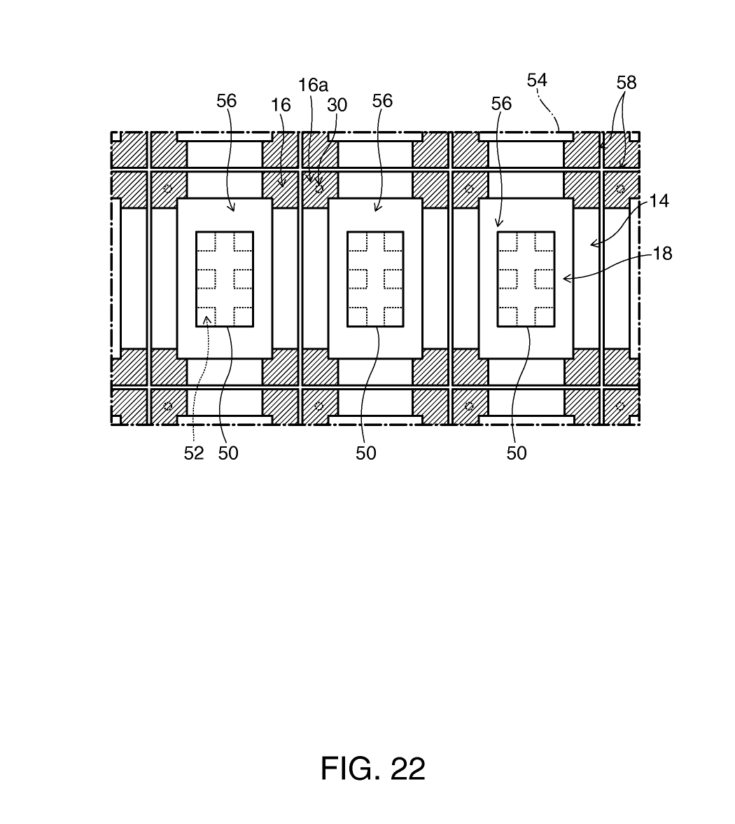

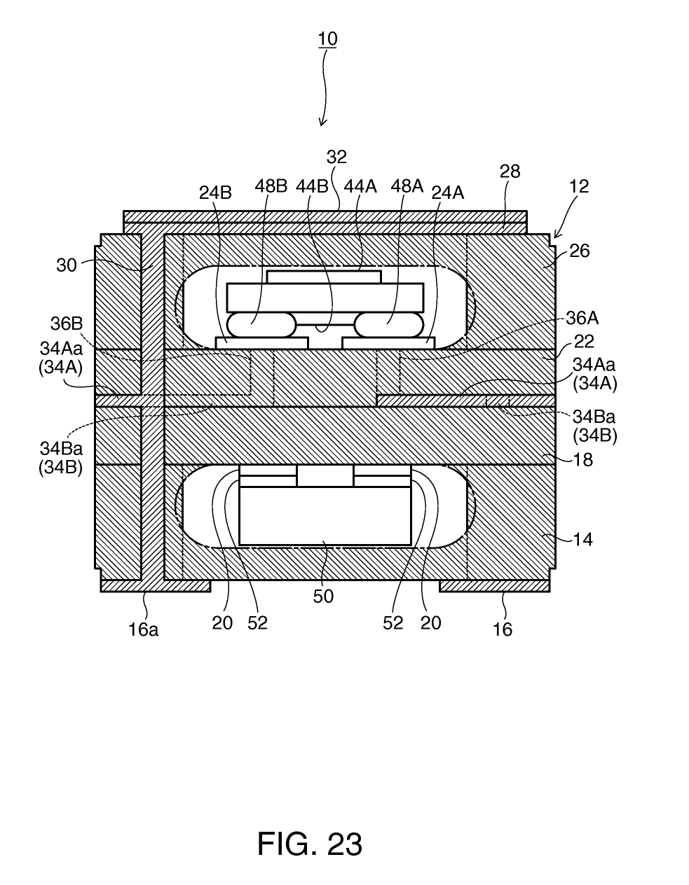

A plan view of an electronic component (before singulation) according to a third embodiment is shown in FIG. 20. A sectional view taken along line A-A of FIG. 20 is shown in FIG. 21. A bottom view of the electronic component (before singulation) according to the third embodiment is shown in FIG. 22. A sectional view of the electronic component (after singulation) according to the third embodiment, which is a sectional view based on a line further on the right side than a step portion of line A-A of FIG. 20, is shown in FIG. 23. To facilitate explanation, in FIG. 20, in an electronic component 10 drawn in the center, the lid 32 is not shown and, in the electronic component 10 drawn on the right side, the lid 32 and the piezoelectric resonator element 38 are not shown. In FIGS. 21, 23, 24, and 25, portions of the substrate 12 overlapping the piezoelectric resonator elements 38 and the integrated circuits 50 are bored.

As explained in detail below, the electronic component 10 according to this embodiment is obtained by forming a plurality of the electronic components 10 in a collected state on the sheet substrate 54 and thereafter singulating the sheet substrate 54 for each of the substrate regions 56. In this embodiment, after packaging on the sheet substrate 54, the piezoelectric resonator element 38 and the lid 32 arranged in one of the substrate regions 56 (the second substrate regions) present around the substrate region 56 (the first substrate region) in which the piezoelectric resonator element 38 is arranged are connected to each other by the first wire (the wire 34A). The piezoelectric resonator element 38 and the lid 32 present in the substrate region 56 (the first substrate region) in which the piezoelectric resonator element 38 is arranged are electrically connected to each other by the second wire (the wire 34B). The wire 34A includes a path extending across the boundary of the substrate region 56 (the first substrate region). The wire 34B includes a path extending across the boundary of the substrate region 56 (the first substrate region) and returning to the substrate region 56 (the first substrate region) through one of the substrate regions 56 (the second substrate regions) present around the substrate region 56 (the first substrate region).

An input and output inspection for the piezoelectric resonator element 38 is performed via the lid 32 present in the substrate region 56 (the first substrate region) in which the piezoelectric resonator element 38 is arranged and the lids 32 present in the substrate regions 56 (the second substrate regions) electrically connected to the piezoelectric resonator element 38. The wires 34A and 34B are fragmented in the singulation of the electronic component 10. When the input and output inspection after the packaging of the piezoelectric resonator element 38 is performed, the substrate region 56 in which the piezoelectric resonator element 38 to be inspected is arranged is set as the first substrate region and the substrate regions 56 present around the first substrate region are set as the second substrate regions.

As shown in FIG. 23, the electronic component 10 according to this embodiment is a piezoelectric device configured by the substrate 12 formed of an insulating material such as ceramic, the piezoelectric resonator element 38 (the electronic element), the integrated circuit 50 (the second electronic element) electrically connected to the piezoelectric resonator element 38, and the lid 32 (the lid body) having electrical conductivity such as metal. The piezoelectric device receives power supply from the outside to thereby oscillate by itself.

The substrate 12 forming the external shape of the electronic component 10 has a four-layer structure including the first frame-like substrate 14, the first center substrate 18, the second center substrate 22, and the second frame-like substrate 26 in order from the bottom. As shown in FIG. 23, the cross section of the substrate 12 is an H shape.

The first frame-like substrate 14 has a rectangular frame shape in plan view. The first frame-like substrate 14 is joined to the first center substrate 18 to thereby form a housing space for housing the integrated circuit 50. Packaged electrodes 16 are provided on the lower surface of the first frame-like substrate 14.

The integrated circuit 50 is packaged on the lower surface of the first center substrate 18. The connection electrodes 20 are provided in positions opposed to the pad electrodes 52 of the integrated circuit 50.

The piezoelectric resonator element 38 is packaged on the upper surface of the second center substrate 22. The mount electrodes 24A and 24B (two terminals) are arranged in positions joined to the piezoelectric resonator element 38. The mount electrodes 24A and 24B are electrically connected to a part of the connection electrodes 20 via through-electrodes (not shown in the figure) that pierce through the first center substrate 18 and the second center substrate 22. Therefore, the piezoelectric resonator element 38 and the integrated circuit 50 are electrically connected.

The second frame-like substrate 26 has a rectangular frame shape in plan view. The second frame-like substrate 26 is joined to the second center substrate 22 to thereby form a housing space for housing the piezoelectric resonator element 38. The metallization 28 (FIG. 20) (a conductive pattern) having a frame shape is provided on the upper surface of the second frame-like substrate 26. The lid 32 is joined to the metallization 28. The metallization 28 is electrically connected to the packaged electrode 16a via a through-electrode (FIG. 23) that pierces through the second frame-like substrate 26, the second center substrate 22, the first center substrate 18, and the first frame-like substrate 14.

The lid 32 is joined to the metallization 28 present around the opening of the second frame-like substrate 26 to seal the opening. Therefore, it is possible to seal the piezoelectric resonator element 38 in a vacuum by joining the lid 32 to the metallization 28 under a vacuum environment.

On the other hand, it is possible to earth the lid 32 joined to the metallization 28 by earthing the packaged electrode 16a. The connection electrodes 20 connected to the pad electrodes 52 for earthing of the integrated circuit 50 are electrically connected to the through-electrode 30.

In this embodiment, the wires 34A (34Aa) and 34B (34Ba) exposed to the side surfaces of the substrate 12 are provided on the second center substrate 22 (or the first center substrate 18).

As shown in FIG. 23, the wire 34Aa is formed in a position opposed to the mount electrode 24A on the lower surface of the second center substrate 22 and is electrically connected to the mount electrode 24A via the through-electrode 36A. The wire 34Aa extends to the side surface of the substrate 12. The wire 34Aa is the wire 34A on the sheet substrate 54 before singulation as explained below.

The wire 34Ba is formed in a position opposed to the mount electrode 24B on the lower surface of the second center substrate 22 and is electrically connected to the mount electrode 24B via the through-electrode 36B. The wire 34Ba extends in a direction opposite to the direction of the wire 34Aa to the side surface of the substrate 12. The wire 34Ba is the wire 34B on the sheet substrate 54 before singulation as explained below. As shown in FIG. 23, the wire 34Ba is connected to the wire 34Aa. The wire 34Aa extends from the through-electrode 30. As explained below, the wire 34Aa is formed by merging of the wires 34A and 34B before the division of the sheet substrate 54.

As shown in FIGS. 20 and 23, the piezoelectric resonator element 38 is formed of a piezoelectric material such as quartz. In this embodiment, the piezoelectric resonator element 38 is, for example, a thickness-shear resonator element including an AT cut substrate of quartz. The piezoelectric resonator element 38 includes the vibrating section 40 that performs thickness-slip vibration and the mount section 42 joined to the second center substrate 22. The exciting electrode 44A is arranged on the upper surface of the vibrating section 40. The exciting electrode 44B is arranged on the lower surface of the vibrating section 40. The extracting electrode 46A (FIG. 20) is drawn out from the exciting electrode 44A. The extracting electrode 46B (FIG. 20) is drawn out from the exciting electrode 44B. The extracting electrode 46A is drawn out to the lower surface of the mount section 42. The extracting electrode 46B is drawn out to the lower surface of the mount section 42 through the upper surface and the side surface of the mount section 42.

The extracting electrodes 46A and 46B and the mount electrodes 24A and 24B are joined by conductive adhesives 48A and 48B to join the mount section 42 to the second center substrate 22. Consequently, the piezoelectric resonator element 38 is supported on the substrate 12 in a cantilevered state and electrically connected to the integrated circuit 50. As the piezoelectric resonator element 38, besides the above, a tuning fork type resonator element, a dual tuning fork type resonator element, a SAW resonator element, and a gyro resonator element can be applied.

The integrated circuit 50 is obtained by integrally forming an oscillating circuit driven by the piezoelectric resonator element 38 functioning as an oscillation source, a temperature compensating circuit that performs temperature compensation for an oscillation signal, and the like. The pad electrodes 52 are arranged on an active surface (the upper surface) of the integrated circuit 50. As the pad electrodes 52, there are connection terminals (X1 and X2) electrically connected to the piezoelectric resonator element 38. The pad electrodes 52 are respectively electrically connected to the mount electrodes 24A and 24B via through-electrodes (not shown in the figure). The pad electrodes 52 are a power supply terminal (Vcc) that receives power supply from the outside, a ground terminal (GND), an output terminal (O/P) for an oscillation signal, and a terminal for adjustment for performing writing of a program. The pad electrodes 52 are respectively electrically connected to the packaged electrodes 16. The ground terminal (GND) is electrically connected to the packaged electrodes 16(16a). Therefore, the number of the packaged electrodes 16 is designed according to the number of pad electrodes 52 of the integrated circuit 50.

As shown in FIGS. 20 to 22, the sheet substrate 54 is a member before singulation of the substrate 12 of the electronic component 10. On the sheet substrate 54, the substrate regions 56, each of which is a portion for forming one electronic component 10, are sectioned in a matrix shape. The dividing grooves 58 for dividing the sheet substrate 54 are formed in boundaries among the substrate regions 56.

As shown in FIG. 21, the sheet substrate 54 has a four-layer structure including the first sheet substrate 60, the second sheet substrate 62, the third sheet substrate 64, and the fourth sheet substrate 66 in order from the bottom.

The first sheet substrate 60 is a member before singulation of the first frame-like substrates 14. The first sheet substrate 60 has a form in which the first frame-like substrates 14 are collected in a matrix shape. The dividing grooves 58 for dividing the sheet substrate 54 are formed on the lower surface of the first sheet substrate 60.

The second sheet substrate 62 is a member before singulation of the first center substrates 18. The second sheet substrate 62 has a form in which the first center substrates 18 are collected in a matrix shape. The third sheet substrate 64 is a member before singulation of the second center substrates 22. The third sheet substrate 64 has a form in which the second center substrates 22 are collected in a matrix shape.

The fourth sheet substrate 66 is a member before singulation of the second frame-like substrates 26. The fourth sheet substrate 66 has a form in which the second frame-like substrates 26 are collected in a matrix shape. The dividing grooves 58 for dividing the sheet substrate 54 are formed on the upper surface of the fourth sheet substrate 66.

As shown in FIGS. 20 and 21, the wires 34A and 34B electrically connected to the mount electrodes 24A and 24B via the through-electrodes 36A and 36B are arranged on the third sheet substrate 64 (or the second sheet substrate 62).

The wire 34A electrically connected to the mount electrode 24A extends to the right side from a position right under the mount electrode 24A. The wire 34A includes a path extending from the substrate region 56, which includes the mount electrodes 24A, to a position of the substrate region 56 on the right side of the dividing groove 58, where the metallization 28 is arranged, across the dividing groove 58. The wire 34A is electrically connected to the metallization 28 via the through-electrode 30.

The wire 34B electrically connected to the mount electrode 24B extends to the left side from a position right under the mount electrode 24B. The wire 34B includes a path extending from the substrate region 56, which includes the mount electrode 24B, to the substrate region 56 on the left side of the dividing groove 58 across the dividing groove 58, merging with the wire 34A present in the substrate region 56, and returning to the original substrate region 56.

Therefore, the wire 34A electrically connects the piezoelectric resonator element 38 and the lid 32 of one substrate regions 56 among the substrate regions 56 (the second substrate regions) present around the substrate region 56 (the first substrate region) in which the piezoelectric resonator element 38 is arranged. The wire 34B electrically connects the piezoelectric resonator element 38 and the lid 32 of the substrate region 56 (the first substrate region) in which the piezoelectric resonator element 38 is arranged.

As shown in FIG. 21, the exciting electrode 44A of the piezoelectric resonator element 38 drawn in the center is electrically connected to the lid 32 of the substrate region 56 (the electronic component 10) on the right side via the extracting electrode 46A (FIG. 20), the conductive adhesive 48A, the mount electrode 24A, the through-electrode 36A, the wire 34A, and the through-electrode 30. Similarly, the exciting electrode 44B is electrically connected to the lid 32 of the substrate region 56 (the electronic component 10), in which the exciting electrode 44B is arranged, via the extracting electrode 46B (FIG. 20), the conductive adhesive 48B, the mount electrode 24B, the through-electrode 36B, the wire 34B, and the through-electrode 30.

In this embodiment, before the sheet substrate 54 is divided, the piezoelectric resonator elements 38 arranged in the respective substrate regions 56 (the first substrate regions) are electrically connected to the lids 32 arranged in the substrate regions 56 (the second substrate regions) adjacent to the substrate regions 56 (the first substrate regions) and the lids 32 of the substrate regions 56 (the first substrate regions) in which the piezoelectric resonator elements 38 are arranged. That is, in an input and output inspection for the piezoelectric resonator element 38 after being packaged on the sheet substrate 54, it is possible to use the lids 32, which forms the upper surface of the electronic component 10, as inspection electrodes as well without providing the inspection electrodes anew. Therefore, it is possible to secure a contact area of the inspection electrodes on the electronic component 10 side required by the inspection probe 68 explained below and suppress a decrease in a portion for forming the substrate regions 56 (the electronic component 10) on the sheet substrate 54.

On the other hand, the wires 34A and 34B are fragmented by dividing the sheet substrate 54 along the dividing grooves 58. The piezoelectric resonator element 38 can be electrically connected to only the integrated circuit 50 arranged in the same substrate region 56. Since the lids 32 after the division of the sheet substrate 54 are earthed, parasitic capacitance is not caused for the piezoelectric resonator element 38. Therefore, the sheet substrate 54 and the electronic component 10 are realized in which occurrence of parasitic capacitance for the piezoelectric resonator element 38 after the division of the sheet substrate 54 is reduced.

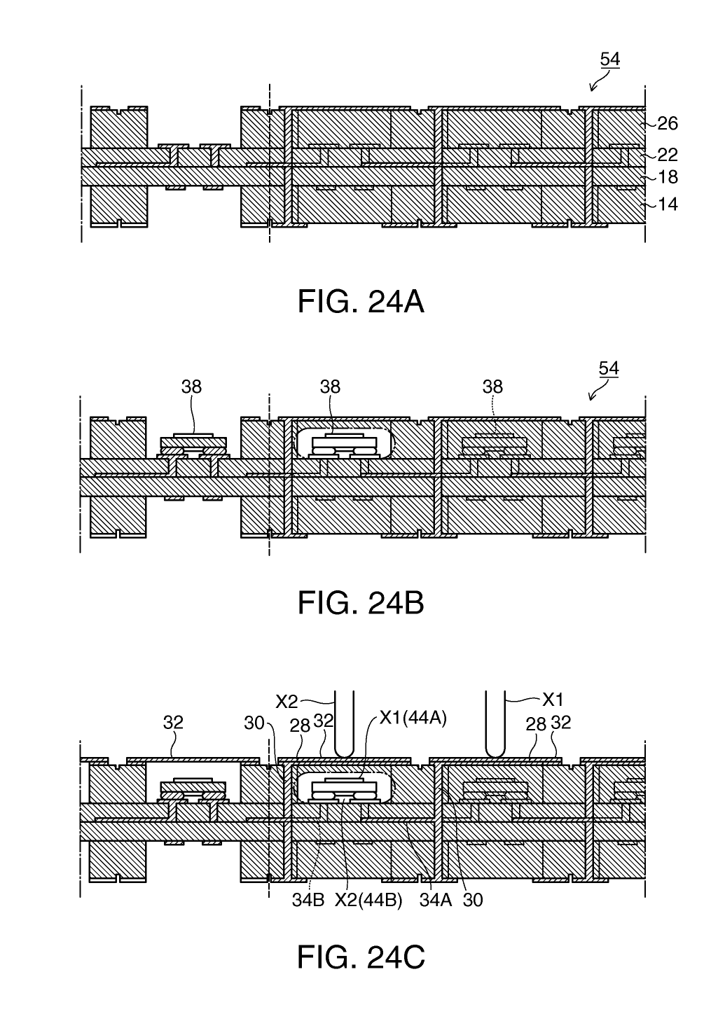

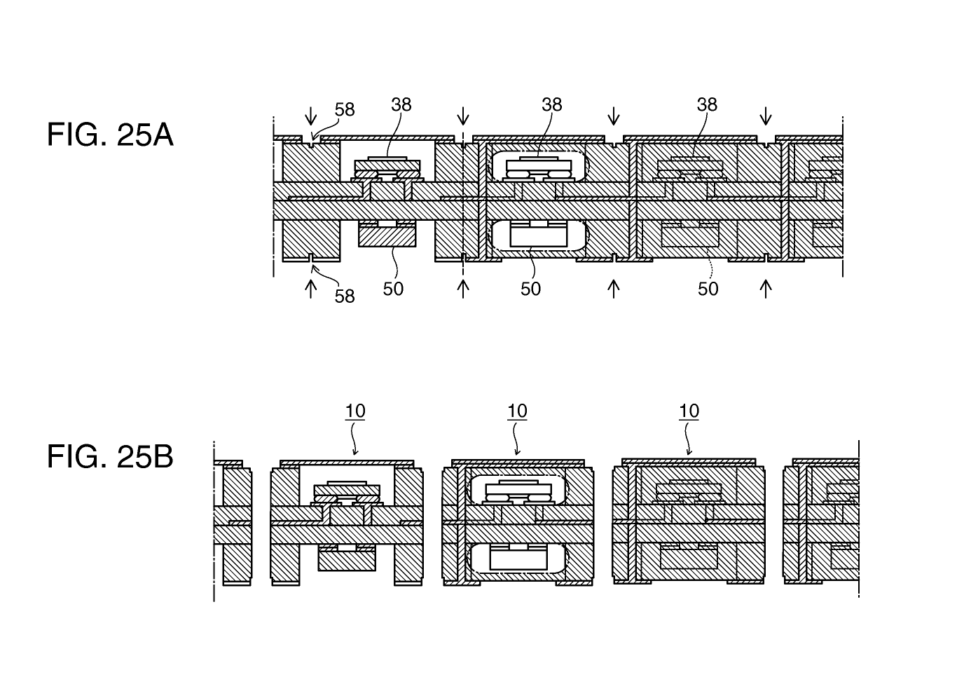

A manufacturing process for the electronic component according to the third embodiment is explained. The manufacturing process for the electronic component according to the third embodiment is shown in FIGS. 24A to 24C and FIGS. 25A and 25B.

As shown in FIG. 24A, the first sheet substrate 60, the second sheet substrate 62, the third sheet substrate 64, and the fourth sheet substrate 66 are formed and are laminated to form the sheet substrate 54.

As shown in FIG. 24B, the piezoelectric resonator elements 38 are packaged in the respective substrate regions 56. As shown in FIG. 24C, the lids 32 are joined in the respective substrate regions 56. The inspection probes 68 are brought into contact with the lid 32 of the substrate region (the first substrate region) in which the piezoelectric resonator element 38 to be inspected is packaged and the lids 32 of the substrate regions 56 (the second substrate regions) adjacent to the substrate region 56 (the first substrate region). When an input and output inspection for the piezoelectric resonator element 38 is performed using the inspection probes 68, it is possible to specify an inoperable piezoelectric resonator element 38 or, even when the piezoelectric resonator element 38 operates, specify the piezoelectric resonator element 38, a resonance frequency and a CI value of which deviate from allowable ranges.

In the manufacturing process in this embodiment, identification inspection information in which position information of the inspection probes 68 and acceptance and rejection by an inspection of the piezoelectric resonator element 38 are associated with each other is generated. A manipulator (not shown in the figures) attached to the integrated circuit 50 is actuated on the basis of the identification inspection information. The integrated circuit 50 is not packaged in the substrate region 56 including the piezoelectric resonator element 38 rejected on the basis of the identification inspection information. The integrated circuit 50 is packaged in only the substrate region 56 in which the packaged piezoelectric resonator element 38 satisfactorily operates. Consequently, it is possible to prevent a loss of the integrated circuit 50 and suppress costs.

Blades (not shown in the figures) are pressed against the sheet substrate 54 along the dividing grooves 58 of the sheet substrate 54 as shown in FIG. 25A, whereby the electronic component 10 is singulated as shown in FIG. 25B. According to the singulation, the wires 34A and 34B are fragmented in the dividing grooves 58 set as boundaries. However, the wires 34Aa and 34Ba (FIG. 23) remain in the electronic component 10.

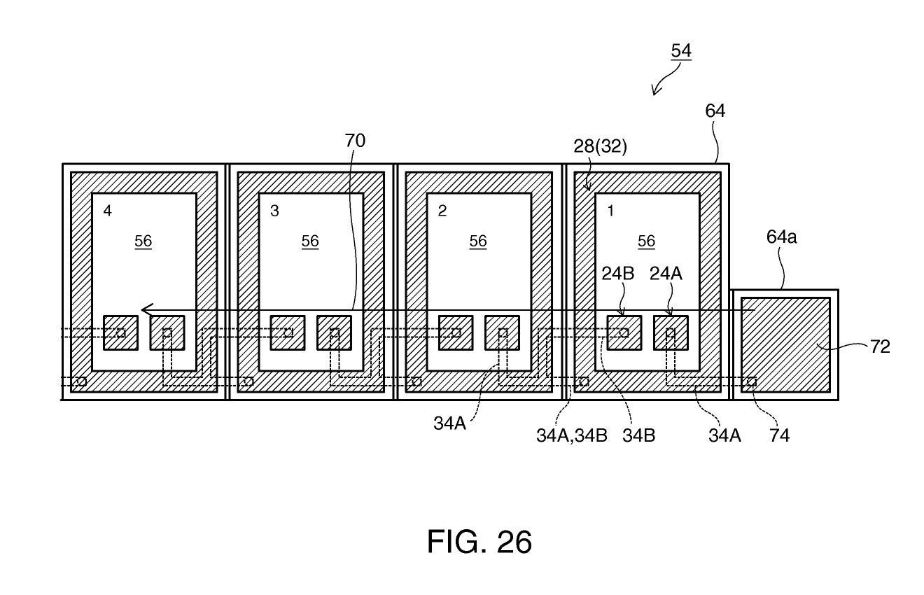

In FIGS. 26 to 31, patterns of wires and paths of an inspection process in the electronic component (before singulation) according to the third embodiment are shown. In FIGS. 26 to 31, the lids 32 and the piezoelectric resonator elements 38 are not shown.

When an inspection of the electronic component 10 is performed, the path 70 that alternately passes the boundaries of the substrate regions 56, across which the wires 34A and 34B extend, and the substrate regions 56 in which the wires 34A and 34B are arranged is in a direction in which the inspection probes 68 are moved from the substrate region 56 to be inspected to the substrate region 56 to be inspected next. In the path 70, when the piezoelectric resonator element 38 in a kth (an integer) substrate region 56 that the path 70 passes is inspected, the inspection probes 68 are brought into contact with the lid 32 of the kth substrate region 56 (first substrate region) and the lid 32 of a (k−1)th substrate region 56 (second substrate). However, the substrate region 56 (the lid 32) to which one of the wires 34A and 34B is connected is absent in the substrate regions 56 at the start end and the terminal end of the path 70.

Therefore, as shown in FIG. 26, it is necessary to separately provide a substrate piece 64a. For example, in the third sheet substrate 64 (or the second sheet substrate 62) on which the wires 34A and 34B are arranged, substrate pieces 64a and 64b are left in positions adjacent to the substrate regions 56 at the start end and the terminal end of the path 70. The inspection electrode 72 is formed on the upper surface of the substrate piece 64a. The wire 34A is extended to the lower surface of the substrate piece 64a. A pattern for electrically connecting the inspection electrode 72 and the wire 34A via the through-electrode 74 piercing through the substrate piece 64a is formed. On the other hand, on the lower surface of the substrate piece 64b, a pattern for extending the wire 34B and extending the wire 34B to the original substrate region 56 and connecting the wire 34B to the metallization 28 (the lid 32) is formed.

As shown in FIG. 26, in an inspection from the right to the left, when the inspection of the piezoelectric resonator element 38 in the first substrate region 56 is performed, the inspection probes 68 only have to be brought into contact with the inspection electrode 72 and the lid 32 of the first substrate region 56. When the inspection of the piezoelectric resonator element 38 in the fourth (last) substrate region 56 is performed, the inspection probes 68 only have to be brought into contact with the lid 32 of the third substrate region 56 and the lid 32 of the fourth substrate region 56.

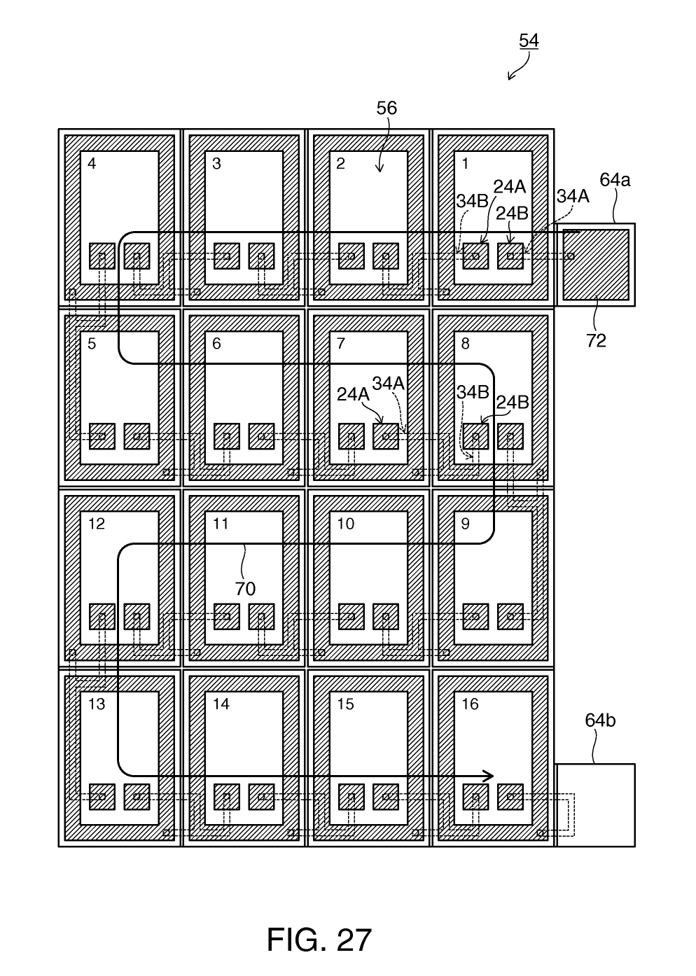

FIG. 26 shows the substrate regions 56 (the electronic component 10) arranged in a lateral row on the sheet substrate 54. When the substrate regions 56 are arranged in a matrix shape on the sheet substrate 54, in the patterns of the wires 34A and 34B, the substrate pieces 64a need to be prepared at both ends of the respective rows. A portion for forming the substrate regions 56 (the electronic component 10) on the sheet substrate 54 decreases. Therefore, as shown in FIGS. 27 to 31, when the substrate regions 56 (the electronic component 10) are sectioned in a matrix shape (4×4=16) on the sheet substrate 54, the patterns of the wires 34A and 34B are devised.

In FIG. 26, the wire 34A is a one-way path extending to another substrate region 56. The wire 34B is a return path extending to another substrate region 56 and returning to the original substrate region 56.

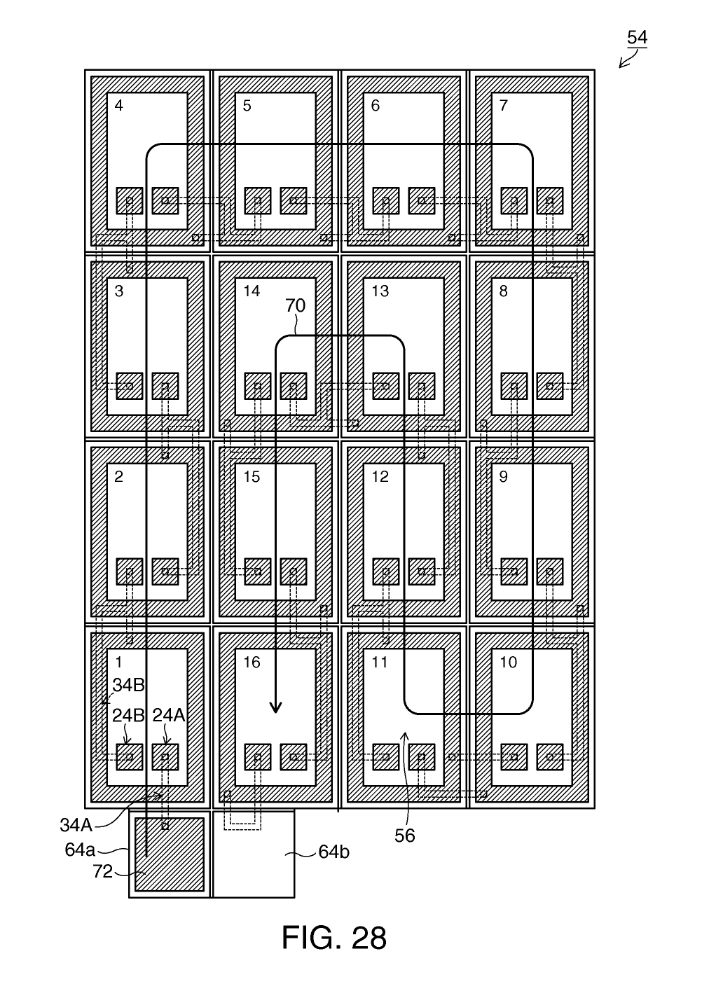

On the other hand, in FIGS. 27 and 28, in the wires 34A and 34B, patterns for respectively setting directions extending across the boundary of the substrate region 56 to arbitrary directions and arbitrarily selecting a one-way path and a return path are used, whereby the path 70 passing all the substrate regions 56 in one-stroke sketch is established. In FIGS. 27 and 28, the last substrate region 56 to be inspected is present adjacent to the first substrate region 56 to be inspected. In the figures, a wire extending from a position overlapping the mount electrode 24A in plan view is the wire 34A and a wire extending from a position overlapping the mount electrode 24B in plan view is the wire 34B.

Consequently, only two substrate pieces 64a have to be provided. The substrate pieces 64a are provided only on one side of the sheet substrate 54. Therefore, it is possible to suppress a decrease in a portion for forming the sheet substrate 54.

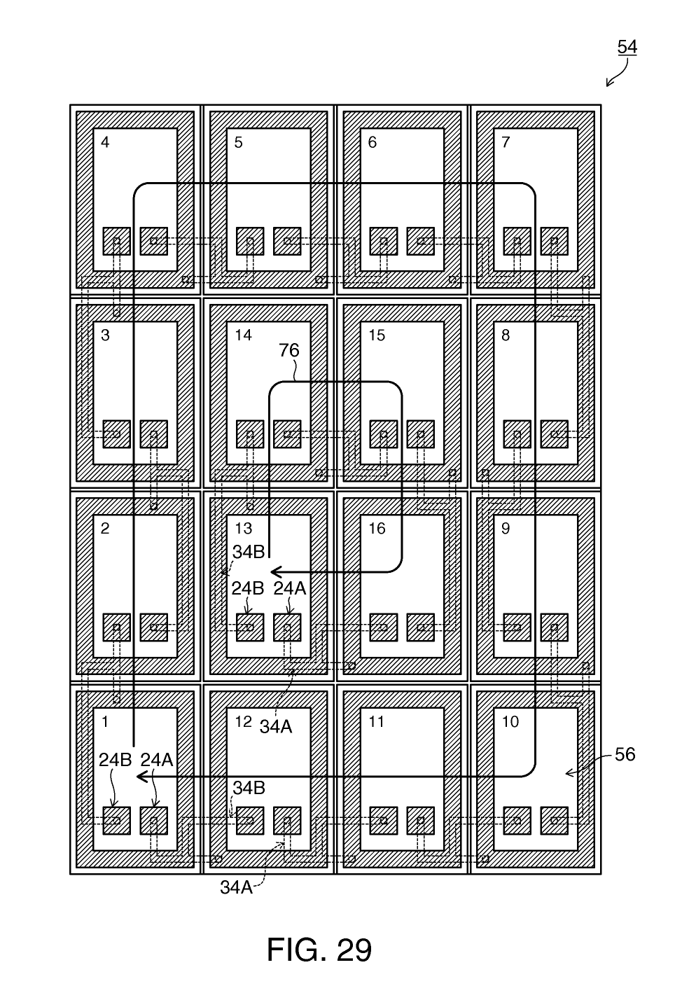

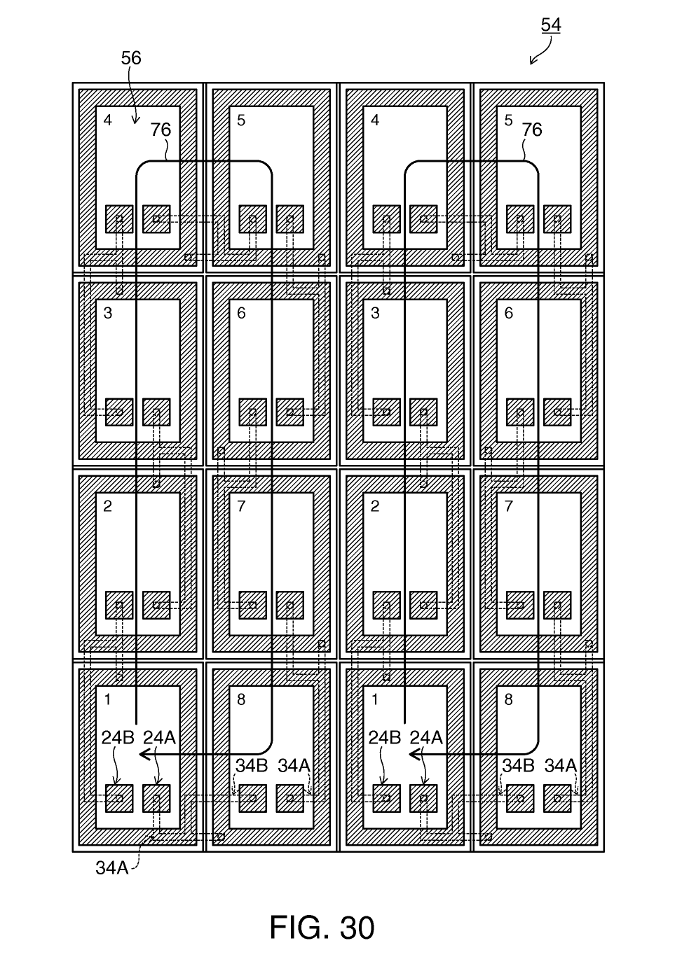

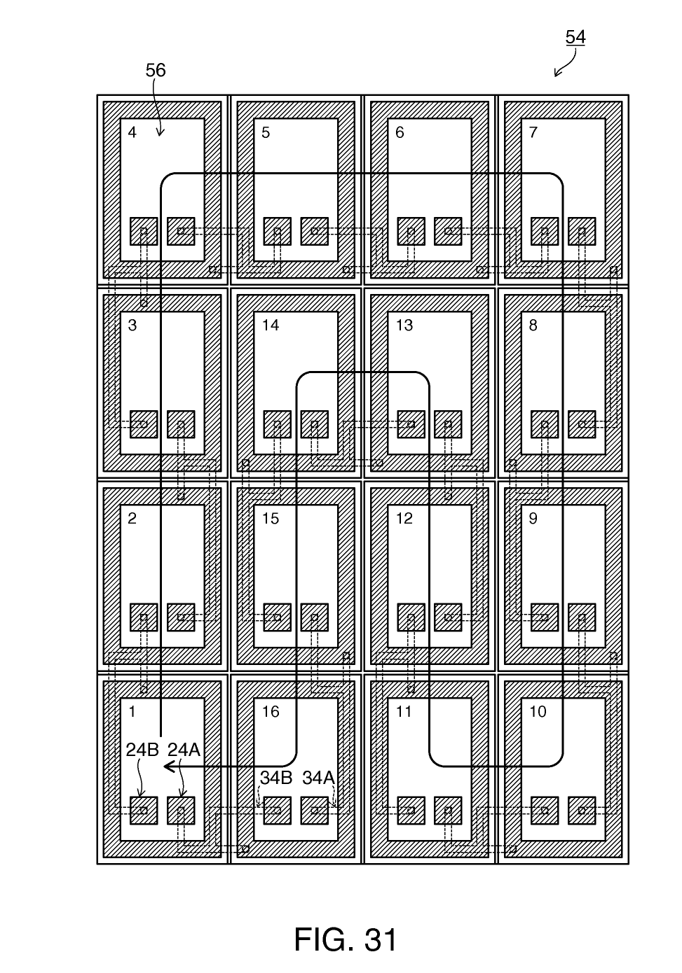

In FIGS. 29 to 31, the patterns explained above are used to build the path 76 circulating through the substrate regions 56. In FIG. 29, the path 76 circulating through the substrate regions 56 forming the peripheral edge of the sheet substrate 54 and the path 76 circulating on the inner side of the substrate regions 56 are built. All the substrate regions 56 are covered by the two paths 76. In FIG. 30, all the substrate regions 56 are covered by the two paths 76 in a form in which the paths 76 circulating through the substrate regions 56 are arranged side by side. In FIG. 31, the path 76 not only circulating through the substrate regions 56 but also passing through the substrate regions 56 in one-stroke sketch to cover all the substrate regions 56 is built. By building the paths 76 shown in FIGS. 29 to 31, the substrate pieces 64a are made unnecessary. It is possible to prevent a decrease in a portion for forming the sheet substrate 54.

In FIG. 29, when the inspection of the piezoelectric resonator element 38 in the first substrate region 56 is performed, the inspection probes 68 only have to be brought into contact with the lid 32 of the first substrate regions 56 (the first substrate region) and the lid 32 of the twelfth substrate region 56 (the second substrate region). When the inspection of the piezoelectric resonator element 38 in the twelfth substrate region 56 is performed, the inspection probes 68 only have to be brought into contact with the lids 32 of the twelfth and eleventh substrate regions 56. When the inspection of the piezoelectric resonator element 38 in the thirteenth substrate region 56 is performed, the inspection probes 68 only have to be brought into contact with the lids 32 of the thirteenth and sixteenth substrate regions 56. When the inspection of the piezoelectric resonator element 38 in the sixteenth substrate region 56 is performed, the inspection probes 68 only have to be brought into contact with the lids 32 of the sixteenth and fifteenth substrate regions 56.

In FIG. 30, when the inspection of the piezoelectric resonator element 38 in the first substrate region 56 is performed, the inspection probes 68 only have to be brought into contact with the lid 32 of the first substrate regions 56 (the first substrate region) and the lid 32 of the eighth substrate region 56 (the second substrate region). When the inspection of the piezoelectric resonator element 38 in the eighth substrate region 56 is performed, the inspection probes 68 only have to be brought into contact with the lids 32 of the eighth and seventh substrate regions 56.

In FIG. 31, when the inspection of the piezoelectric resonator element 38 in the first substrate region 56 is performed, the inspection probes 68 only have to be brought into contact with the lids 32 of the first substrate region 56 (the first substrate region) and the sixteenth substrate region 56 (the second substrate region). When the inspection of the piezoelectric resonator element 38 in the sixteenth substrate region 56 is performed, the inspection probes 68 only have to be brought into contact with the lids 32 of the sixteenth and fifteenth substrate regions 56.

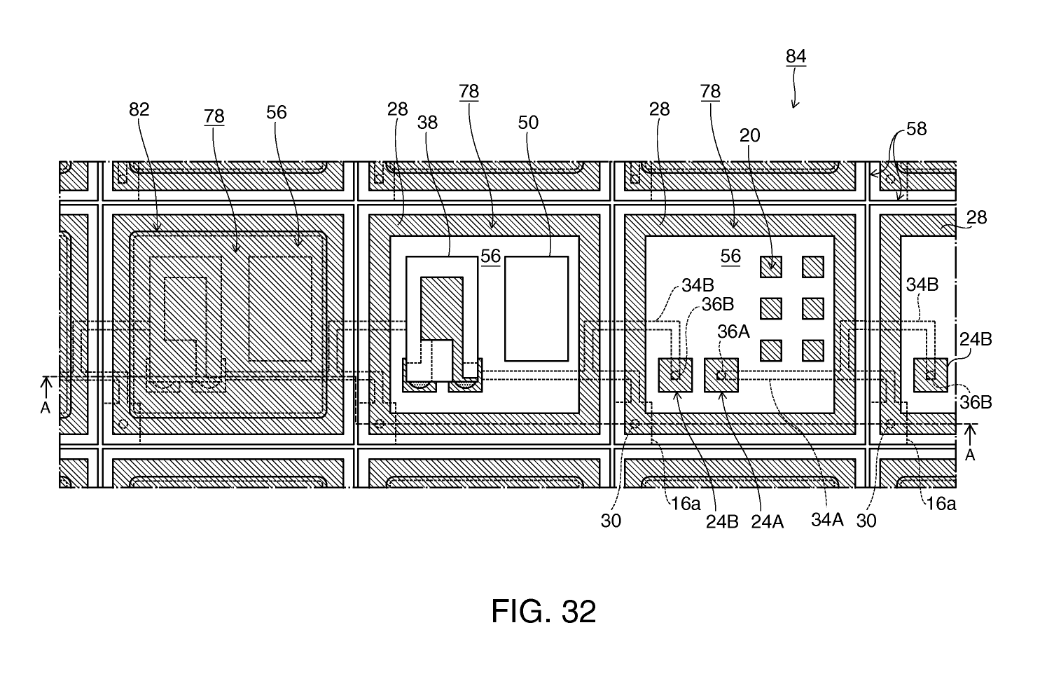

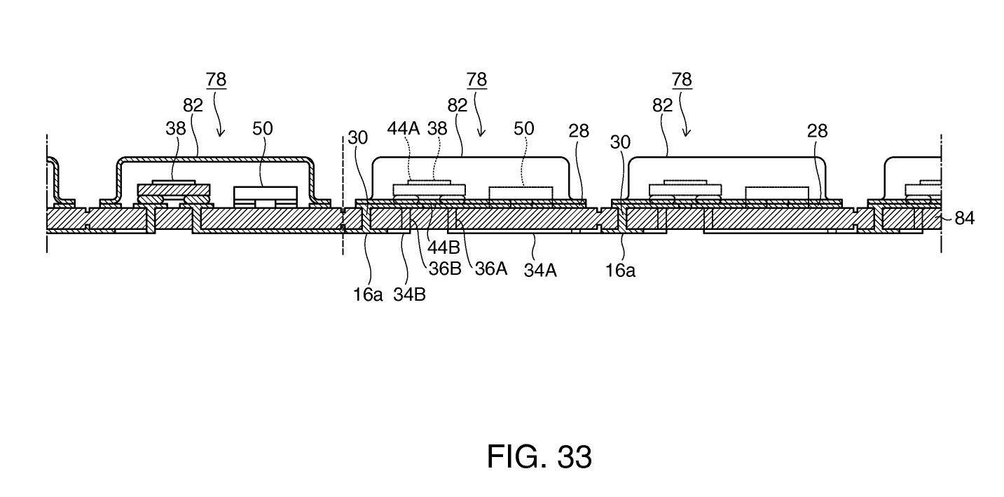

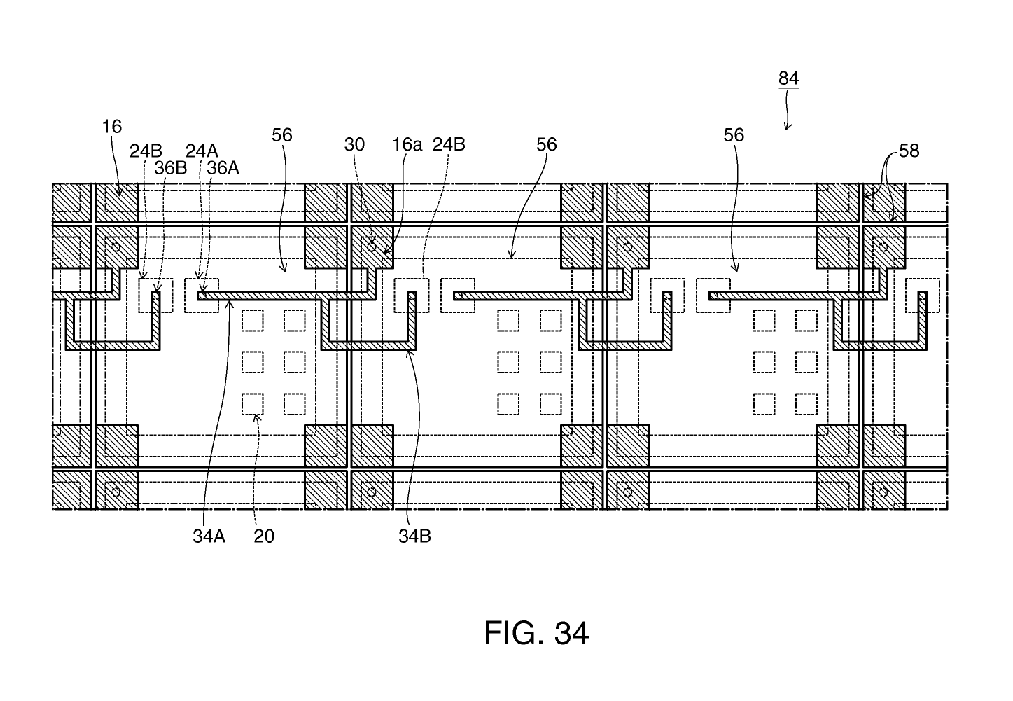

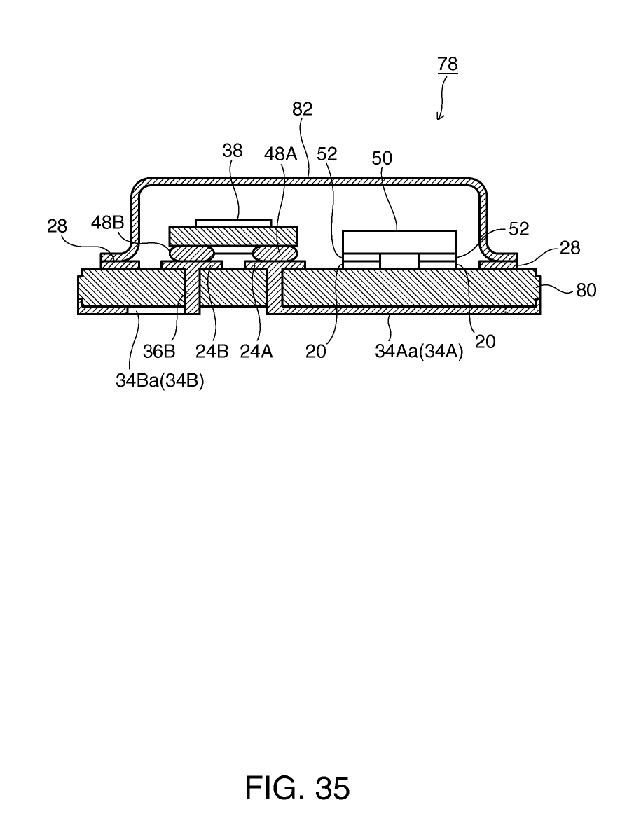

A plan view of an electronic component (before singulation) according to a fourth embodiment is shown in FIG. 32. A sectional view taken along line A-A of FIG. 32 is shown in FIG. 33. A bottom view of the electronic component (before singulation) according to the fourth embodiment is shown in FIG. 34. A sectional view of the electronic component (after singulation) according to the fourth embodiment is shown in FIG. 35. In the following explanation, components common to the third embodiment are denoted by the same reference numerals and signs. Explanation of the components is omitted except when necessary.

As shown in FIG. 35, in the electronic component 78 according to the fourth embodiment, the piezoelectric resonator element 38 and the integrated circuit 50 are arranged on the same surface of the substrate 80. The piezoelectric resonator element 38 and the integrated circuit 50 are sealed by the cap 82 (a lid body). The cap 82 is formed by a conductive member such as metal. The cap 82 has a housing space for housing the piezoelectric resonator element 38 and the integrated circuit 50 and hermetically seals the piezoelectric resonator element 38 and the integrated circuit 50.

As shown in FIGS. 32 to 35, the sheet substrate 84 used as a material of the substrate 80 is one sheet. The dividing grooves 58 forming the boundaries among the substrate regions 56 are provided on the upper surface and the lower surface of the sheet substrate 84. The mount electrodes 24A and 24B for packaging the piezoelectric resonator elements 38 and the connection electrodes 20 for packaging the integrated circuits 50 are arranged in the respective substrate regions 56 on the upper surface of the sheet substrate 84. In the respective substrate regions 56, the metallizations 28 joined to the lower surfaces of the caps 82 are arranged in positions around the piezoelectric resonator elements 38 and the integrated circuits 50.

The wires 34A and 34B respectively electrically connected to the mount electrodes 24A and 24B via the through-electrodes 36A and 36B are arranged in positions opposed to the mount electrodes 24A and 24B on the lower surface of the sheet substrate 84.

In FIGS. 32 and 35, the wire 34A extends to the right side from the position opposed to the mount electrode 24A. The wire 34A is connected to the packaged electrode 16a of the substrate region 56 on the right side across the boundary of the substrate region 56. The packaged electrode 16a is electrically connected to the metallization 28 via the through electrode 30. On the other hand, the wire 34B extends to the left side from the position opposed to the mount electrode 24B and extends to a position of the metallization 28 of the substrate region 56 on the left side across the boundary of the substrate region 56. The wire 34B is electrically connected to the metallization 28 (the cap 82) via the through-electrode 30.

Therefore, the piezoelectric resonator element 38 in the substrate region 56 (the electronic component 78) in the center shown in FIG. 33 is electrically connected to the cap 82 arranged in the substrate region 56 and the cap 82 arranged in the substrate region 56 on the right side of the substrate region 56.

In a manufacturing process for the electronic component 78 in the fourth embodiment, after the piezoelectric resonator element 38 and the integrated circuit 50 are packaged on the sheet substrate 84, the cap 82 is joined to the sheet substrate 84. An inspection of the piezoelectric resonator element 38 to be inspected can also be performed by bringing the inspection probes 68 into contact with the cap 82 arranged in the substrate region 56 (the first substrate region) in which the piezoelectric resonator element 38 is packaged and the cap 82 arranged in the substrate region 56 (the second substrate region) on the right side of the substrate region 56 (the first substrate region). However, when the piezoelectric resonator element 38 is rejected by the inspection, even if the integrated circuit 50 packaged in the substrate region 56 in which the piezoelectric resonator element 38 is packaged normally operates, there is a loss of the integrated circuit 50. Therefore, the inspection is performed as explained below.

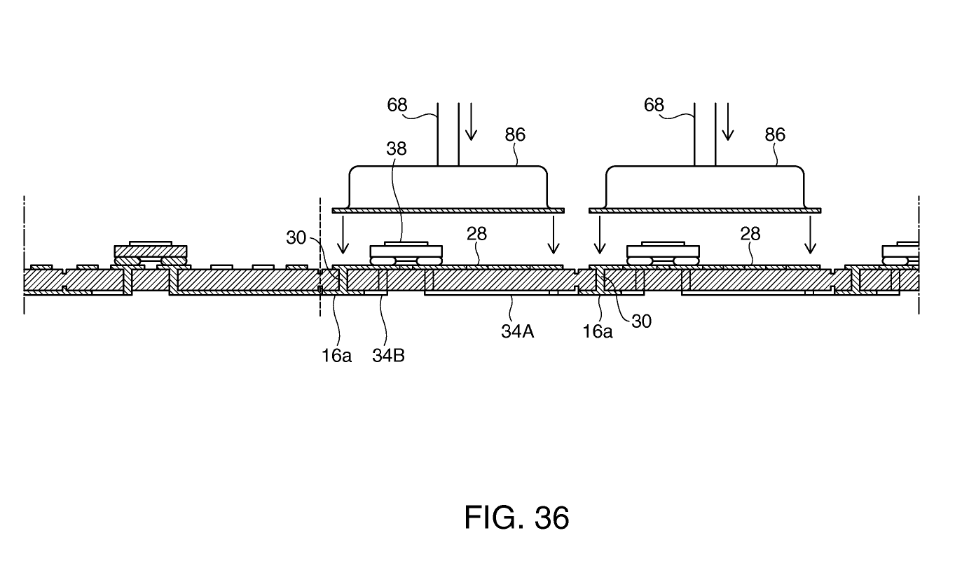

An inspection method for the electronic component (before singulation) according to the fourth embodiment is shown in FIG. 36. FIG. 36 is a sectional view taken along line A-A of FIG. 32. A state before attachment of the integrated circuit 50 and the cap 82 is shown.

As shown in FIG. 36, the piezoelectric resonator elements 38 are packaged in the respective substrate regions 56 of the sheet substrate 84. For example, as shown in FIG. 36, the inspection members 86 having the same shape as the caps 82 are attached to the tips of the inspection probes 68. The inspection members 86 are brought into contact with the metallization 28 in the substrate region 56 (the first substrate region) in which the piezoelectric resonator element 38 to be inspected is packaged and the metallization 28 in the substrate region 56 (the second substrate region) on the right side of the substrate region 56 (the first substrate region). Consequently, it is possible to package the integrated circuit 50 only in the substrate region 56 in which the piezoelectric resonator element 38 accepted by the inspection is packaged and join the cap 82 to the substrate region 56. Therefore, it is possible to prevent a loss of the integrated circuit 50 and the cap 82.

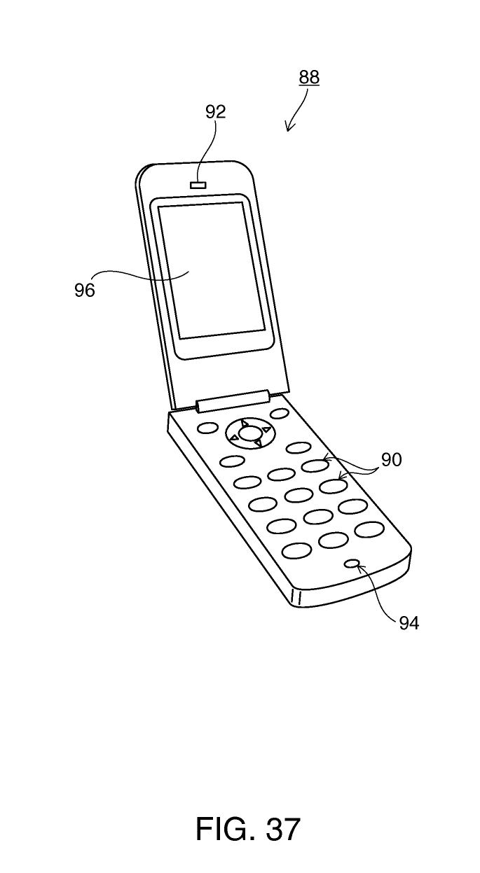

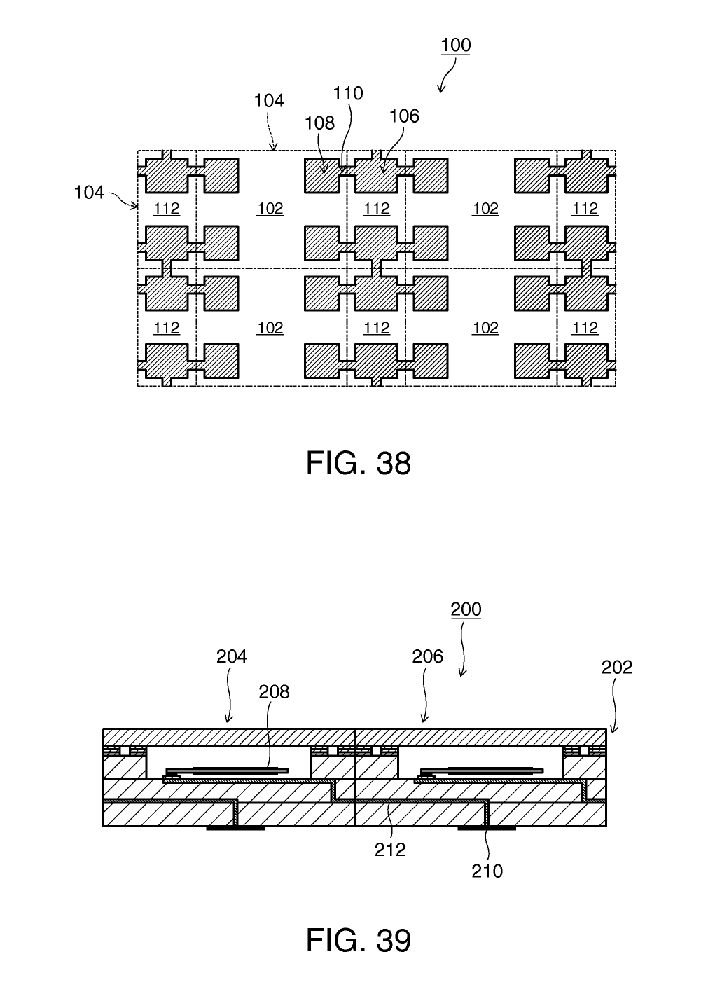

A schematic diagram of an electronic apparatus (a portable terminal) mounted with the electronic component according to this embodiment is shown in FIG. 37. In FIG. 37, a portable terminal 88 (including a PHS) includes a plurality of operation buttons 90, an earpiece 92, and a mouthpiece 94. A display unit 96 is arranged between the operation buttons 90 and the earpiece 92. Recently, even such a portable terminal includes a GPS function. Therefore, the electronic component 10 or 78 (a piezoelectric device) according to this embodiment is incorporated in the portable terminal 88 as a clock source of a GPS circuit.

The electronic apparatus including the electronic component 10 or 78 according to this embodiment can be applied to, besides the portable terminal 88, for example, a high-performance mobile phone, a digital still camera, a personal computer, a laptop personal computer, a television, a video camera, a video recorder, a car navigation apparatus, a pager, an inkjet discharging apparatus, an electronic organizer, an electronic calculator, an electronic game machine, a word processor, a work station, a television phone, a security television monitor, an electronic binocular, a POS terminal, medical equipment (e.g., an electronic thermometer, a sphygmomanometer, a blood glucose meter, an electrocardiogram measuring apparatus, an ultrasonic diagnostic apparatus, and an electronic endoscope), a fish-finder, various measuring apparatuses, meters (e.g., meters for vehicles, airplanes, and ships), and a flight simulator.

The entire disclosure of Japanese Patent Application Nos. 2012-110169, filed May 14, 2012, and 2012-112202, filed May 16, 2012 are expressly incorporated by reference herein.

What is claimed is:

1. A manufacturing method for an electronic component comprising:
preparing a sheet substrate on which a first substrate region, a second substrate region arranged to be integrated with the first substrate region, two terminals arranged in the first substrate region, a first conductive pattern arranged in the first substrate region, a second conductive pattern arranged in the second substrate region, and a first wire that electrically connects one of the two terminals and the second conductive pattern are arranged;
electrically connecting an electronic element to the two terminals;
arranging a first lid body on the first conductive pattern and electrically connecting the first conductive pattern and the first lid body, arranging a second lid body on the second conductive pattern and electrically connecting the second conductive pattern and the second lid body, and measuring a signal from the electronic element via the second lid body; and
separating the sheet substrate into the first substrate region and the second substrate region.

2. The manufacturing method for an electronic component according to claim 1, wherein
a second wire is further arranged on the sheet substrate and the second wire includes a path returning from the first substrate region to the first substrate region through the second substrate regions and electrically connects the other of the two terminals and the first conductive pattern, and
the manufacturing method further comprises measuring a signal from the electronic element via the first lid body and the second lid body.

3. The manufacturing method for an electronic component according to claim 1, further comprising arranging, after electrically connecting the electronic element to the two terminals, a second electronic element electrically connected to the electronic element in the first substrate region.

4. The manufacturing method for an electronic component according to claim 2, further comprising arranging, after electrically connecting the electronic element to the two terminals, a second electronic element electrically connected to the electronic element in the first substrate region.

5. An inspection method for an electronic component including a sheet substrate on which a first substrate region, a second substrate region arranged to be integrated with the first substrate region, two terminals arranged in the first substrate region, a first conductive pattern arranged in the first substrate region, a second conductive pattern arranged in the second substrate region, and a first wire that electrically connects one of the two terminals and the second conductive pattern are arranged,
the inspection method comprising electrically connecting an electronic element to the two terminals, arranging a first lid body on the first conductive pattern and electrically connecting the first conductive pattern and the first lid body, arranging a second lid body on the second conductive pattern and electrically connecting the second conductive pattern and the second lid body, and performing an inspection of the electronic element via the second lid body.

6. The inspection method for an electronic component according to claim 5, wherein a second wire is further arranged on the sheet substrate and the second wire includes a path returning from the first substrate region to the first substrate region through the second substrate regions and electrically connects the other of the two terminals and the first conductive pattern, and
the inspection method further comprises performing the inspection of the electronic element via the first lid body and the second lid body.

7. A sheet substrate comprising:
a first substrate region;
a second substrate region integrated with the first substrate region;
a first pad arranged in the first substrate region;
a second pad arranged in the second substrate region;
an annular first conductive pattern arranged in the first substrate region and surrounding the first pad; and
an annular second conductive pattern arranged in the second substrate region and surrounding the second pad, wherein
the first pad includes two terminals and a first wire that electrically connects one of the two terminals and the second conductive pattern.

8. The sheet substrate according to claim 7, wherein a second wire is further arranged on the sheet substrate and the second wire includes a path returning from the first substrate region to the first substrate region through the second substrate regions and electrically connects the other of the two terminals and the first conductive pattern.

9. An electronic component, wherein an electronic element and a lid body are arranged in the first substrate region according to claim 7.

10. An electronic component, wherein an electronic element and a lid body are arranged in the first substrate region according to claim 8.

11. An electronic apparatus mounted with the electronic component according to claim 9.

12. An electronic apparatus mounted with the electronic component according to claim 10.
